(19) United States
(12) Patent Application Publication
(10) Pub. No.: US 2026/0226604 A1
(43) Pub. Date: Aug. 6, 2026

(54) DEPOSITION MASK, METHOD OF MANUFACTURING THE SAME, METHOD OF MANUFACTURING DISPLAY PANEL USING THE SAME, AND ELECTRONIC DEVICE MANUFACTURED BY USING THE SAME

(71) Applicant: Samsung Display Co., LTD., Yongin-si (KR)

(72) Inventor: Sung Woon KIM, Yongin-si (KR)

(21) Appl. No.: 19/351,596

(22) Filed: Oct. 7, 2025

(30) Foreign Application Priority Data
Feb. 6, 2025 (KR) 10-2025-0015106

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes a mask substrate provided with a cell opening, and a membrane disposed on a front surface of the mask substrate and provided with a plurality of pixel openings communicating with the cell opening. An inner side surface of the mask substrate defining the cell opening has a stripe-shaped surface profile extending in a thickness direction of the mask substrate.

This application claims priority to Korean Patent Application No. 10-2025-0015106, filed on Feb. 6, 2025, and all the benefits accruing therefrom under 35 U.S.C. § 119, the content of which in its entirety is herein incorporated by reference.

### BACKGROUND

### 1. Field

The present disclosure relates to a deposition mask, a method of manufacturing the deposition mask, a method of manufacturing a display panel using the deposition mask, and an electronic device manufactured by using the deposition mask.

### 2. Description of the Related Art

Wearable devices in which a focus is formed at a distance close to user's eyes have been developed in the form of glasses or a helmet. For example, the wearable device may be a head mounted display (HMD) device or augmented reality (AR) glasses. The wearable device may provide an AR screen or a virtual reality (VR) screen to a user.

In the case of wearable devices such as the HMD device or the AR glasses, a display specification of approximately 3000 pixels per inch (PPI) or higher is desired to allow users to use them for a long time without symptoms of dizziness. To this end, organic light emitting diode on silicon (OLEDoS) technology is emerging for use in a high-resolution small organic light emitting display device. The OLEDOS is a technology in which organic light emitting diodes (OLED) are arranged on a semiconductor substrate on which complementary metal oxide semiconductor (CMOS) elements are arranged.

In order to manufacture a display panel with a high resolution of about 3000 PPI or higher, a high-resolution deposition mask may be used. For example, the deposition mask may be manufactured by forming a membrane having a plurality of pixel openings on a front surface of a mask substrate, and partially removing the mask substrate to form cell openings that expose the pixel openings.

### SUMMARY

In a deposition mask, the cell openings may be formed by forming a rear inorganic film with rear openings on the rear surface of the mask substrate, and then performing an etching process that uses the rear inorganic film as an etching mask. For example, the cell openings may be formed by a wet etching process using an etching solution such as a tetramethylammonium hydroxide (TMAH) solution, a potassium hydroxide (KOH) solution, or an ethylene diamine pyrocatechol (EDP) solution. In this case, the cell openings may have a width that gradually decreases from the rear surface of the mask substrate toward the front surface of the mask substrate. As a result, the cross-sectional area of the rib region of the mask substrate that defines the cell openings may be reduced, thereby reducing the structural stability of the deposition mask.

Embodiments of the present disclosure provide a deposition mask with improved structural stability, a method of manufacturing the deposition mask, a method of manufacturing a display panel using the deposition mask, and an electronic device manufactured by using the deposition mask.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

In accordance with an embodiment of the present disclosure, a deposition mask includes a mask substrate provided with a cell opening, and a membrane disposed on a front surface of the mask substrate and provided with a plurality of pixel openings communicating with the cell opening. In such an embodiment, an inner side surface of the mask substrate defining the cell opening has a stripe-shaped surface profile extending in a thickness direction of the mask substrate.

In accordance with some embodiments, the inner side surface of the mask substrate defining the cell opening may be perpendicular to a rear surface of the mask substrate or have an inclination angle of about 85° or greater with respect to the rear surface of the mask substrate.

In accordance with some embodiments, the deposition mask may further include a rear inorganic film disposed on a rear surface of the mask substrate and provided with a rear opening exposing the cell opening.

In accordance with some embodiments, the rear opening may have a same width as the cell opening.

In accordance with some embodiments, the rear inorganic film may include a same material as the membrane and have a same thickness as the membrane.

In accordance with some embodiments, the cell opening may include a first opening adjacent to the rear inorganic film and a second opening adjacent to the membrane, and the stripe-shaped surface profile may be formed on an inner side surface portion of the mask substrate defining the first opening.

In accordance with some embodiments, the inner side surface portion of the mask substrate defining the first opening may be perpendicular to the rear surface of the mask substrate or have an inclination angle of about 85° or greater with respect to the rear surface of the mask substrate, and the second opening may have a width which gradually decreases from the first opening toward the membrane.

In accordance with some embodiments, an inner side surface portion of the mask substrate defining the second opening may have an inclination angle of about 54.7° with respect to the rear surface of the mask substrate.

In accordance with some embodiments, the rear opening may have a same width as the first opening.

In accordance with an embodiment of the present disclosure, a method of manufacturing a deposition mask includes forming a membrane having a plurality of pixel openings on a front surface of a mask substrate, and forming a cell opening communicating with the pixel openings through the mask substrate by partially removing a portion of the mask substrate. In such an embodiment, an inner side surface of the mask substrate defining the cell opening has a stripe-shaped surface profile extending in a thickness direction of the mask substrate.

In accordance with some embodiments, the forming of the cell opening may include forming a metal catalyst pattern on a rear surface of the mask substrate, and performing a metal assisted chemical etching process on the mask substrate using the metal catalyst pattern to form the cell opening.

In accordance with some embodiments, in the performing the metal assisted chemical etching process, the metal catalyst pattern may be moved in the thickness direction of the mask substrate, and the stripe-shaped surface profile may be formed while the metal catalyst pattern is moved.

In accordance with some embodiments, the metal catalyst pattern may include at least one selected from gold (Au), silver (Ag), platinum (Pt), and palladium (Pd).

In accordance with some embodiments, the metal catalyst pattern may have a single-layer structure or a double-layer structure.

In accordance with some embodiments, the metal catalyst pattern may have a thickness in a range of about 3 nanometers (nm) to about 10 nm.

In accordance with some embodiments, the metal assisted chemical etching process may be performed using an etching solution comprising an oxidizing agent, an etchant, and a solvent.

In accordance with some embodiments, the oxidizing agent may include at least one selected from hydrogen peroxide (H₂O₂), silver nitrate (AgNO₃), chloroauric acid (HAuCl₄), chloroplatinic acid (H₂PtCl₆), iron nitrate (Fe(NO₃)₃), nickel nitrate (Ni(NO₃)₂), magnesium nitrate (Mg(NO₃)₂), sodium persulfate (Na₂S₂O₈), potassium permanganate (KMnO₄), and potassium dichromate (K₂Cr₂O₇).

In accordance with some embodiments, the etchant may include hydrofluoric acid (HF).

In accordance with some embodiments, the solvent may include water, ethanol or a mixed solution of water and ethanol.

In accordance with some embodiments, the forming the cell opening may further include removing the metal catalyst pattern after the performing the metal assisted chemical etching process.

In accordance with some embodiments, the forming the cell opening may further include removing etching residues after the performing the metal assisted chemical etching process.

In accordance with some embodiments, the forming the cell opening may include forming a plurality of metal catalyst patterns on a rear surface of the mask substrate, and performing a metal assisted chemical etching process on the mask substrate using the metal catalyst patterns to form the cell opening.

In accordance with some embodiments, the forming of the cell opening may include forming a plurality of metal catalyst patterns on a rear surface of the mask substrate, performing a metal assisted chemical etching process on the mask substrate using the metal catalyst patterns to form preliminary cell openings penetrating the mask substrate, and removing partition walls between the preliminary cell openings to form the cell opening.

In accordance with some embodiments, the inner side surface of the mask substrate defining the cell opening may be perpendicular to a rear surface of the mask substrate or have an inclination angle of about 85° or greater with respect to the rear surface of the mask substrate.

In accordance with some embodiments, the method may further include forming a rear inorganic film on a rear surface of the mask substrate, and patterning the rear inorganic film to form a rear opening that partially exposes the rear surface of the mask substrate.

In accordance with some embodiments, the cell opening may be formed to penetrate a rear portion of the mask substrate exposed by the rear opening.

In accordance with some embodiments, the forming the cell opening may include forming a metal catalyst pattern on a rear portion of the mask substrate exposed by the rear opening, and performing a metal assisted chemical etching process on the mask substrate using the metal catalyst pattern to form the cell opening.

In accordance with some embodiments, the forming the cell opening may include forming a metal catalyst pattern on a rear portion of the mask substrate exposed by the rear opening, performing a metal assisted chemical etching process on the mask substrate using the metal catalyst pattern to form a first opening extending from the rear surface of the mask substrate in the thickness direction of the mask substrate, removing the metal catalyst pattern, and forming a second opening connecting the first opening and the pixel openings through the mask substrate.

In accordance with some embodiments, an inner side surface portion of the mask substrate defining the first opening may be perpendicular to the rear surface of the mask substrate or have an inclination angle of 85° or greater with respect to the rear surface of the mask substrate, and the second opening may have a width which gradually decreases from the first opening toward the membrane.

In accordance with some embodiments, an inner side surface portion of the mask substrate defining the second opening may have an inclination angle of about 54.7° with respect to the rear surface of the mask substrate.

In accordance with some embodiments, the second opening may be formed by a wet etching process using a tetramethylammonium hydroxide (TMAH) solution, a potassium hydroxide (KOH) solution, or an ethylene diamine pyrocatechol (EDP) solution.

In accordance with some embodiments, the forming the cell opening may further include forming a liner pattern on inner side surfaces of the first opening, and removing the liner pattern after forming the second opening.

In accordance with some embodiments, the forming the liner pattern may include forming a rear passivation film on the rear inorganic film and inner surfaces of the first opening and the rear opening, and removing a portion of the rear passivation film on the rear inorganic film and a portion of the rear passivation film on a bottom surface of the first opening.

In accordance with some embodiments, the forming the cell opening may further include forming a front passivation film on the membrane and inner surfaces of the pixel openings after forming the first opening, and removing the front passivation film after forming the second opening.

In accordance with an embodiment of the present disclosure, a method of manufacturing a deposition mask includes forming a membrane having a plurality of pixel openings on a front surface of a mask substrate, and partially removing the mask substrate to form a cell opening communicating with the pixel openings. In such an embodiment, at least a part of the cell opening is formed using a metal assisted chemical etching process.

In accordance with an embodiment of the present disclosure, a method of manufacturing a display panel includes placing a backplane substrate on a deposition mask, and providing a vapor-phase light emitting material through the deposition mask to form a plurality of light emitting layers on the backplane substrate. In such an embodiment, the deposition mask includes a mask substrate provided with a cell opening, and a membrane disposed on a front surface of the mask substrate and provided with a plurality of pixel openings communicating with the cell opening. In such an embodiment, an inner side surface of the mask substrate defining the cell opening has a stripe-shaped surface profile extending in a thickness direction of the mask substrate, and the vapor-phase light emitting material is provided onto the backplane substrate through the cell opening and the plurality of pixel openings.

In accordance with an embodiment of the present disclosure, an electronic device includes a display panel. In such an embodiment, the display panel includes a backplane substrate and a plurality of light emitting layers formed by using a deposition mask on the backplane substrate. In such an embodiment, the deposition mask includes a mask substrate having a cell opening, and a membrane disposed on a front surface of the mask substrate and having a plurality of pixel openings communicating with the cell opening. In such an embodiment, an inner side surface of the mask substrate defining the cell opening has a stripe-shaped surface profile extending in a thickness direction of the mask substrate, and the plurality of light emitting layers is formed by a deposition process which provides a vapor-phase light emitting material onto the backplane substrate through the cell opening and the plurality of pixel openings.

In accordance with some embodiments, the electronic device may further include at least one selected from a processor, a memory, and a power module.

According to embodiments of the present disclosure described herein, the cross-sectional area of the rib region of the mask substrate that defines the cell opening may be increased. As a result, the structural stability of the deposition mask may be improved, thereby reducing the warpage of the deposition mask.

Other features and embodiments may be apparent from the following detailed description and the drawings.

### BRIEF DESCRIPTION OF THE DRAWINGS

The above and other features of embodiments of the present disclosure will become more apparent by describing in detail embodiments thereof with reference to the accompanying drawings, in which:

FIG. 1 is a block diagram of an electronic device according to an embodiment of the present disclosure;

FIG. 2 is a schematic diagram of an electronic device according to various embodiments of the present disclosure;

FIG. 3 is an exploded perspective view illustrating a display device according to an embodiment of the present disclosure;

FIG. 4 is a block diagram illustrating the display device shown in FIG. 3;

FIG. 5 is an equivalent circuit diagram illustrating an example of a first sub-pixel shown in FIG. 4;

FIG. 6 is a schematic plan view illustrating an example of a display panel shown in FIG. 3;

FIG. 7 is a schematic enlarged plan view illustrating an example of a display area shown in FIG. 6;

FIG. 8 is a schematic enlarged plan view illustrating another example of the display area shown in FIG. 6;

FIG. 9 is a schematic cross-sectional view illustrating an example of the display panel taken along line I1-I1′ shown in FIG. 7;

FIG. 10 is a schematic cross-sectional view illustrating another example of the display panel taken along line I1-I1′ shown in FIG. 7;

FIG. 11 is a schematic cross-sectional view illustrating still another example of the display panel taken along line I1-I1′ shown in FIG. 7;

FIG. 12 is a schematic perspective view illustrating one example of a head mounted display;

FIG. 13 is a schematic exploded perspective view illustrating the head mounted display shown in FIG. 12;

FIG. 14 is a schematic perspective view illustrating another example of a head mounted display;

FIG. 15 is a schematic diagram illustrating a deposition mask and a deposition apparatus including the deposition mask according to an embodiment of the present disclosure;

FIG. 16 is a schematic bottom view illustrating a backplane substrate shown in FIG. 15;

FIG. 17 is a schematic plan view illustrating a deposition mask shown in FIG. 15;

FIG. 18 is a schematic enlarged plan view illustrating mask cell regions shown in FIG. 17;

FIG. 19 is a schematic cross-sectional view taken along line 12-12′ shown in FIG. 18;

FIG. 20 is a schematic cross-sectional view illustrating another example of the deposition mask shown in FIG. 19;

FIG. 21 is a schematic cross-sectional view illustrating still another example of the deposition mask shown in FIG. 19;

FIGS. 22 to 27 are schematic cross-sectional views illustrating a method of manufacturing a deposition mask according to an embodiment of the present disclosure;

FIGS. 28 to 30 are schematic views illustrating a method of manufacturing a deposition mask according to another embodiment of the present disclosure;

FIGS. 31 to 33 are schematic cross-sectional views illustrating a method of manufacturing a deposition mask according to still another embodiment of the present disclosure;

FIGS. 34 to 37 are schematic cross-sectional views illustrating a method of manufacturing a deposition mask according to still another embodiment of the present disclosure; and

FIGS. 38 to 45 are schematic cross-sectional views illustrating a method of manufacturing a deposition mask according to still another embodiment of the present disclosure.

### DETAILED DESCRIPTION

The invention will now be described more fully hereinafter with reference to the accompanying drawings, in which various embodiments of the disclosure are shown. This invention may, however, be embodied in different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will also be understood that when an element or a layer is referred to as being “on” another element or layer, it can be directly on the other element or layer, or intervening layers may also be present therebetween. In contrast, when an element is referred to as being “directly on” another element, there are no intervening elements present.

It will be understood that, although the terms “first,” “second,” etc. may be used herein to describe various elements, these elements should not be limited by these terms.

These terms are only used to distinguish one element from another element. For instance, a first element discussed below could be termed a second element without departing from the teachings of the disclosure. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

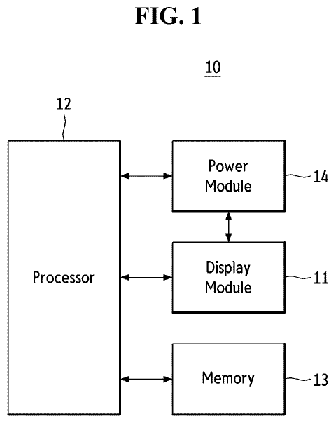

The display device according to embodiments of the present disclosure can be applied to various electronic devices. The electronic device according to an embodiment of the present disclosure includes the display device described herein, and may further include modules or devices having additional functions in addition to the display device. FIG. 1 is a block diagram of an electronic device according to an embodiment of the present disclosure.

Referring to FIG. 1, the electronic device 10 according to an embodiment of the present disclosure may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information used for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example, a power adapter or a battery, and a power conversion module that converts the power supplied by the power supply module to generate power used for the operation of the electronic device 10.

At least one of the components of the electronic device 10 according to an embodiment of the present disclosure may be included in the display device 20 according to the embodiments of the present disclosure. In addition, some modules of the individual modules functionally included in one module may be included in the display device 20, and other modules may be provided separately from the display device 10. For example, the display device 20 may include the display module 11, and the processor 12, the memory 13, and the power module 14 may be provided in the form of other devices within the electronic device 10 other than the display device 20.

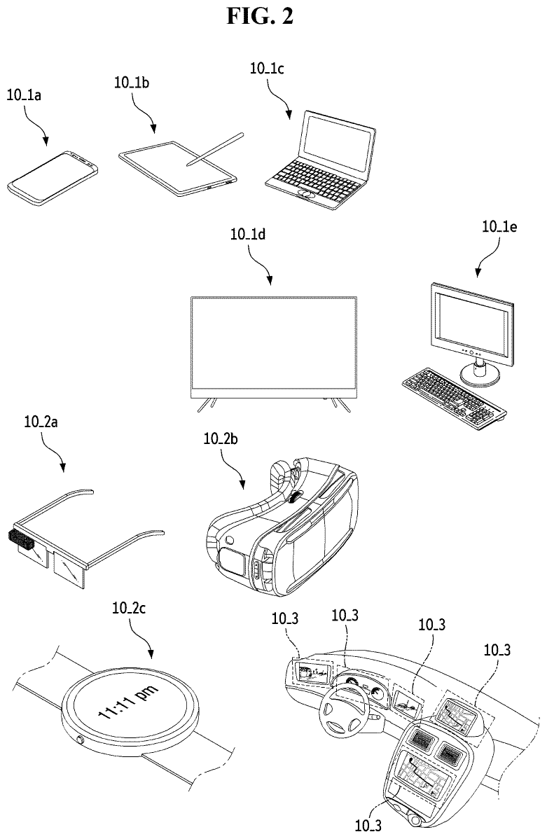

FIG. 2 is a schematic diagram of an electronic device according to various embodiments of the present disclosure.

Referring to FIG. 2, various electronic devices to which display devices 20 according to embodiments of the present disclosure are applied may include not only image display electronic devices such as a smart phone 10_1a, a tablet personal computer (PC) 10_1b, a laptop computer 10_1c, a television (TV) 10_1d, and a desk monitor 10_1e, but also wearable electronic devices including display modules such as, for example, smart glasses 10_2a, a head mounted display 10_2b, and a smart watch 10_2c, and vehicle electronic devices 10_3 including display modules such as a center information display (CID) and a room mirror display arranged on a dashboard, center fascia, and dashboard of an automobile.

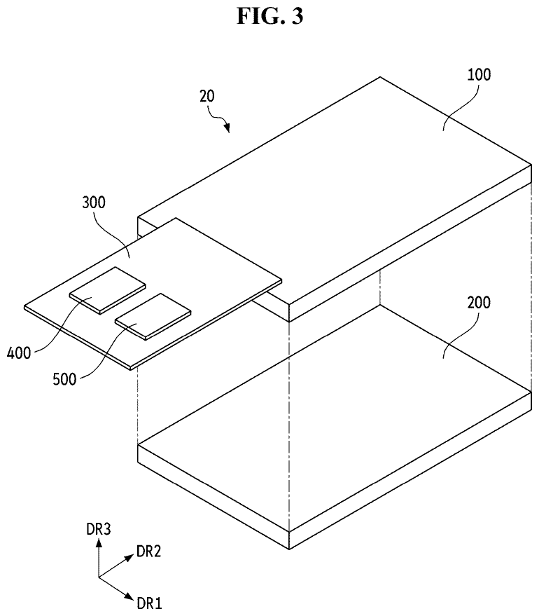

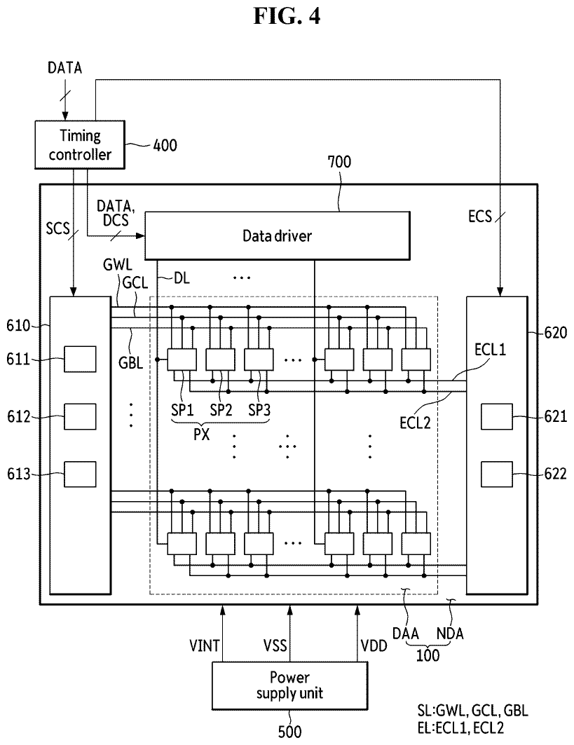

FIG. 3 is an exploded perspective view illustrating a display device according to an embodiment of the present disclosure. FIG. 4 is a block diagram illustrating the display device shown in FIG. 3.

Referring to FIGS. 3 and 4, a display device 20 according to an embodiment may be a device displaying a moving image or a still image. A display device 20 according to an embodiment may be used as the electronic device 10 or the display module 11 of the electronic device 10. In an embodiment, for example, the display device 20 according to an embodiment may be applied to portable electronic devices 10 such as a mobile phone, a smartphone, a tablet personal computer, a mobile communication terminal, an electronic organizer, an electronic book, a portable multimedia player (PMP), a navigation system, an ultra mobile PC (UMPC), and the like. The display device 20 according to an embodiment may be applied as a display module 11 of electronic devices 10 such as a television, a laptop, a monitor, a billboard, or an Internet-of-Things (IOT) terminal, and the like. The display device 20 according to an embodiment may be applied to electronic devices 10 such as a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400, and a power supply circuit 500.

The display panel 100 may have a planar shape similar to a quadrilateral shape. In an embodiment, for example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the present disclosure is not limited thereto.

In an embodiment, as shown in FIG. 4, the display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA for displaying an image and a non-display area NDA in which no image is displayed as shown in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

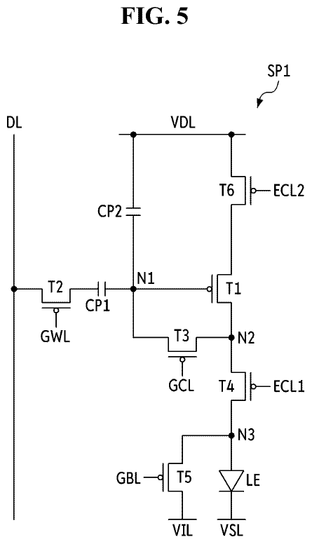

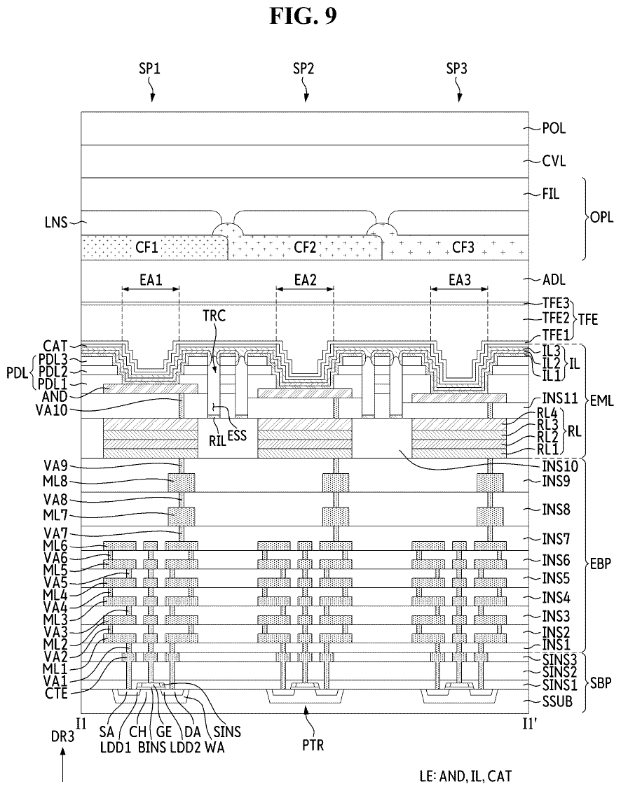

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and disposed on a semiconductor substrate SSUB (see FIG. 9). In an embodiment, for example, the plurality of pixel transistors of the data driver 700 may include or be formed of complementary metal oxide semiconductor (CMOS), but the present disclosure is not limited thereto.

Each of the plurality of sub-pixels SP1, SP2, and SP3 may be connected to a corresponding one write scan line GWL of the plurality of write scan lines GWL, a corresponding one control scan line GCL of the plurality of control scan lines GCL, a corresponding one bias scan line GBL of the plurality of bias scan lines GBL, a corresponding one first emission control line ECL1 of the plurality of first emission control lines ECL1, a corresponding one second emission control line ECL2, and one data line DL of the plurality of second emission control lines ECL2. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. In an embodiment, for example, the plurality of scan transistors and the plurality of light emitting transistors may include or be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and output the write scan signals sequentially to the write scan lines GWL. The control scan signal output unit 612 may generate control scan signals based on the scan timing control signal SCS and sequentially output the control scan signals to the control scan lines GCL. The bias scan signal output unit 613 may generate bias scan signals based on the scan timing control signal SCS and output the bias scan signals sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals based on the emission timing control signal ECS and sequentially output the first emission control signals to the first emission control lines ECL1. The second emission control driver 622 may generate second emission control signals based on the emission timing control signal ECS and sequentially output the second emission control signals to the second emission control lines ECL2.

The data driver 700 may include a plurality of data transistors, and the plurality of data transistors may be formed on the semiconductor substrate SSUB (see FIG. 9) through a semiconductor process. In an embodiment, for example, the plurality of data transistors may include or be formed of CMOS, but the present disclosure is not limited thereto.

The data driver 700 may receive digital video data DATA and a data timing control signal DCS from the timing control circuit 400. The data driver 700 converts the digital video data DATA into analog data voltages based on the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

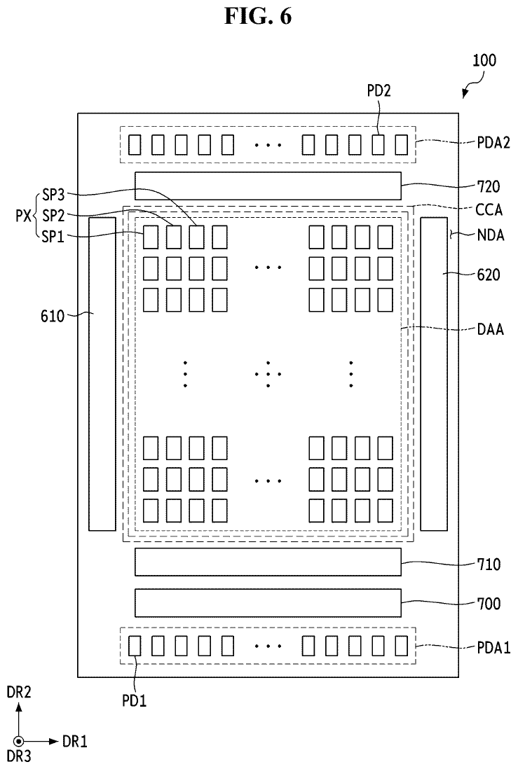

The circuit board 300 may be electrically connected to a plurality of first pads PD1 (see FIG. 6) of a first pad portion PDA1 (see FIG. 6) of the display panel 100 by using a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

In an embodiment, each of the timing control circuit 400 and the power supply circuit 500 may be formed as an integrated circuit (IC) and attached to one surface of the circuit board 300. In such an embodiment, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. In such an embodiment, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. In an embodiment, for example, the plurality of timing transistors and the plurality of power transistors may include or be formed of CMOS, but the present disclosure is not limited thereto. Each of the timing control circuit 400 and the power supply circuit 500 may be disposed between the data driver 700 and the first pad portion PDA1 (see FIG. 6).

FIG. 5 is an equivalent circuit diagram illustrating an example of a first sub-pixel shown in FIG. 4.

Referring to FIG. 5, an embodiment of the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In an embodiment, the first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. In an embodiment, for example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode thereof according to a voltage applied to the gate electrode thereof.

A second transistor T2 may be connected between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be connected between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be connected between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is connected or formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 5 illustrates an embodiment where the first sub-pixel SP1 includes six transistors T1 to T6 and two capacitors C1 and C2, it should be understood that the equivalent circuit diagram of the first sub-pixel SP1 is not limited to that shown in FIG. 5. In an embodiment, for example, the number of transistors and the number of capacitors of the first sub-pixel SP1 are not limited to those shown in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, any repetitive detailed description of the equivalent circuit diagram of the second sub-pixel SP2 and the equivalent circuit diagram of the third sub-pixel SP3 will be omitted.

FIG. 6 is a schematic plan view illustrating an example of a display panel shown in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, for example, the scan driver 610 may be disposed on one side of the display area DAA in the first direction DR1, and the emission driver 620 may be disposed on the other side of the display area DAA in the first direction DR1. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, for example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including or made of a rigid material or a flexible printed circuit board including or made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. In an embodiment, for example, the first distribution circuit 710 may distribute the data voltages applied through one first pad PD1 of the first pad portion PDA1 to the P (P is a positive integer of 2 or greater) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. In an embodiment, for example, the second distribution circuit 720 may be disposed on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed outside at least one side of the display area DAA. In an embodiment, for example, the cathode connection part CCA may be disposed outside at least on one side among the left side, the right side, the upper side, and the lower side of the display area DAA. Alternatively, the cathode connection part CCA may be disposed to surround the display area DAA as shown in FIG. 6 to minimize a deviation in the first driving voltage VSS caused by voltage drop (IR drop) or voltage rise (IR rising) of the second electrode CAT in the display area DAA.

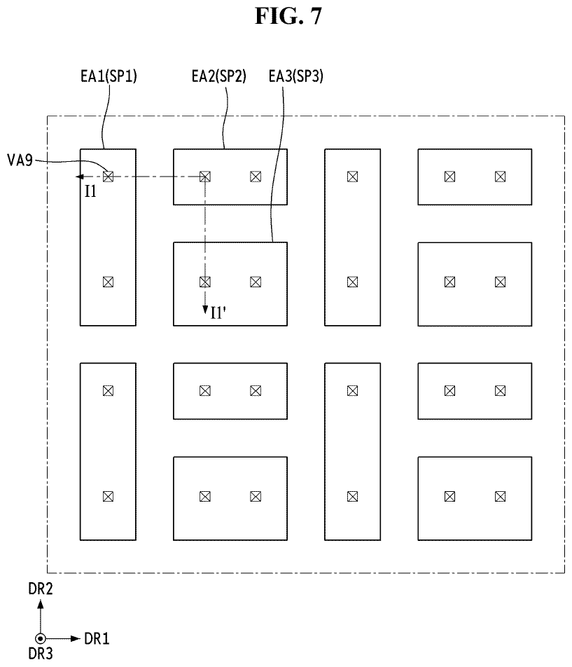

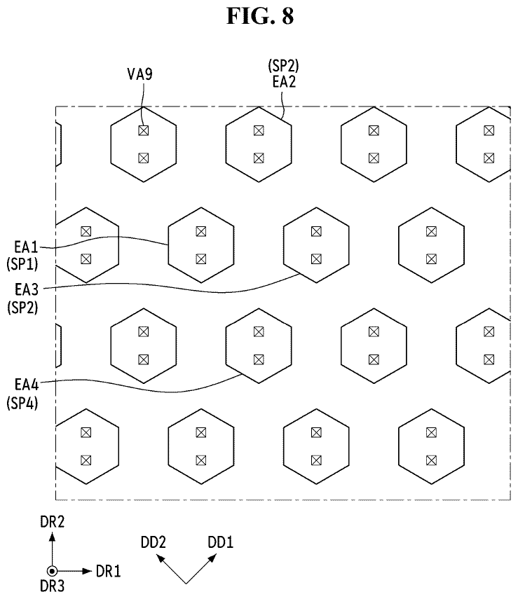

FIG. 7 is a schematic enlarged plan view illustrating an example of a display area shown in FIG. 6. FIG. 8 is a schematic enlarged plan view illustrating another example of the display area shown in FIG. 6.

Referring to FIGS. 7 and 8, in an embodiment, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view (or when viewed in the third direction DR3), a quadrilateral or hexagonal shape as shown in FIGS. 7 and 8, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

As shown in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 8, the emission areas EA1, EA2, EA3, and EA4 may have a hexagonal shape in a plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. In an embodiment, for example, the blue wavelength band may be a wavelength band of light whose main peak wavelength is in a range of approximately 370 nm to 460 nm, the green wavelength band may be a wavelength band of light whose main peak wavelength is in a range of approximately 480 nm to 560 nm, and the red wavelength band may be a wavelength band of light whose main peak wavelength is in a range of approximately 600 nm to 750 nm.

In an embodiment, as shown in FIG. 7, each of the plurality of pixels PX may include three emission areas EA1, EA2, and EA3, or may include four emission areas EA1, EA2, EA3, and EA4 as shown in FIG. 8. In such an embodiment, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape.

FIG. 9 is a schematic cross-sectional view illustrating an example of the display panel taken along line I1-I1′ shown in FIG. 7.

Referring to FIG. 9, an embodiment of the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an embodiment, for example, where the first type impurity is a p-type impurity, the second type impurity may be an n-type impurity. In another embodiment, where the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to a corresponding one of the gate electrode GE, the source region SA, and the drain region DA of each of the pixel transistors PTR through a hole penetrating (formed or defined through) the first semiconductor insulating film SINS1 and the second semiconductor insulating film SINS2. The plurality of contact terminals CTE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include or be formed of silicon carbonitride (SiCN) or a silicon oxide (SiOx)-based inorganic film, but the present disclosure is not limited thereto.

The semiconductor substrate SSUB may be replaced with a glass substrate or a polymer resin substrate such as polyimide. In an embodiment, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

In an embodiment, for example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may include or be formed of substantially the same material as each other. The first to eighth conductive layers ML1 to ML8 and the first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The first to eighth vias VA1 to VA8 may include or be made of substantially the same material as each other. First to eighth interlayer insulating films INS1 to INS8 may include or be formed of a silicon oxide (SiOx)-based inorganic layer, but the present disclosure is not limited thereto.

A ninth interlayer insulating film INS9 may be disposed on the eighth interlayer insulating film INS8 and the eighth conductive layer ML8. The ninth interlayer insulating film INS9 may include or be formed of a silicon oxide (SiOx)-based inorganic film, but the present disclosure is not limited thereto.

Each of the ninth vias VA9 may penetrate the ninth interlayer insulating film INS9 and be connected to the exposed eighth conductive layer ML8. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

The display element layer EML may be disposed on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be disposed on the ninth interlayer insulating film INS9. Each of the reflective electrodes RL may include at least one reflective electrode RL1, RL2, RL3, and RL4. In an embodiment, for example, each of the reflective electrodes RL may include the first to fourth reflective electrodes RL1, RL2, RL3, and RL4 as shown in FIG. 9.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. For example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrodes RL.

The tenth interlayer insulating film INS10 and the eleventh interlayer insulating film INS11 may include or be formed of a silicon oxide (SiOx)-based inorganic film, but the present disclosure is not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as shown in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate (or extend through) the eleventh interlayer insulating film INS11 and be connected to the exposed fourth reflective electrode RL4. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or be formed of a silicon oxide (SiOx)-based inorganic film. Alternatively, the first pixel defining film PDL1 and the third pixel defining film PDL3 may include or be formed of a silicon nitride (SiNx)-based inorganic film, whereas the second pixel defining film PDL2 may include or be formed of a silicon oxide (SiOx)-based inorganic film. The first pixel defining film PDL1, the second pixel defining film PDL2, and the third pixel defining film PDL3 may each have a thickness of about 500 Å.

In an embodiment, the first pixel defining film PDL1, the second pixel defining film PDL2, and the third pixel defining film PDL3 may have a cross-sectional structure having a stepped portion such that the likelihood of the first encapsulation inorganic film TFE1 being cut off due to the step coverage may be substantially reduced or effectively prevented. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed between the neighboring sub-pixels SP1, SP2, and SP3. Although FIG. 9 illustrates an embodiment where two trenches TRC are disposed between the neighboring sub-pixels SP1, SP2, and SP3, the present disclosure is not limited thereto.

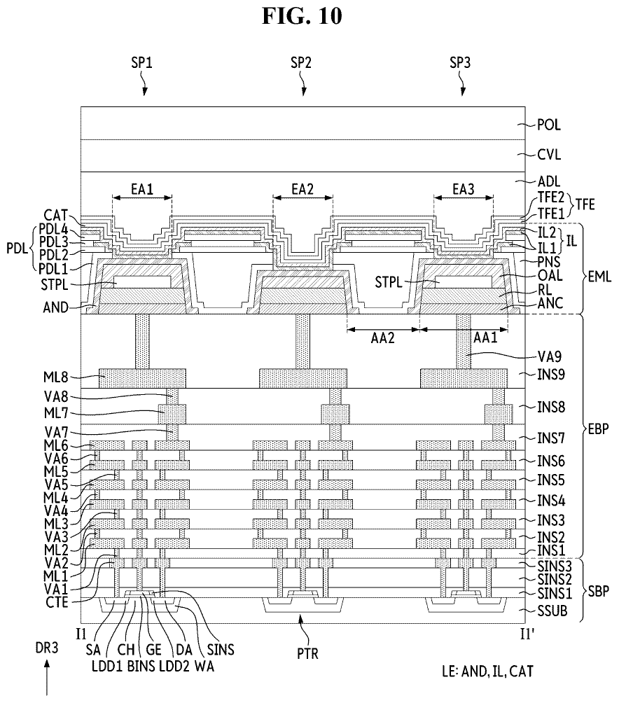

The light emitting stack IL may include a plurality of stack layers IL1, IL2, and IL3. FIG. 9 illustrates an embodiment where the light emitting stack IL has a three-tandem structure including a first stack layer IL1, a second stack layer IL2, and a third stack layer IL3, but the present disclosure is not limited thereto. In another embodiment, for example, the light emitting stack IL may have a two-tandem structure including two stack layers as shown in FIG. 10.

In an embodiment having the three-tandem structure, the light emitting stack IL may have a tandem structure including a plurality of intermediate layers IL1, IL2, and IL3 that emit different lights. In an embodiment, for example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film IL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In an embodiment having the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In an embodiment having the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be disposed on the pixel defining film PDL.

In addition, FIG. 9 illustrates an embodiment where the light emitting stack IL that emits light is disposed in the first emission area EA1, the second emission area EA2, and the third emission area EA3, but the present disclosure is not limited thereto. In another embodiment, for example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light emitting stack IL. That is, the second electrode CAT may be disposed on the third stack layer IL3. The second electrode CAT may include or be formed of a transparent conductive material (TCO) such as ITO or IZO that can transmit light or a semi-transmissive conductive material such as magnesium (Mg), silver (Ag), or an alloy of Mg and Ag. In an embodiment where the second electrode CAT include or is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may include or be formed of multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In addition, the encapsulation layer TFE may include at least one organic film TFE2 to protect the display element layer EML from foreign substances such as dust. The encapsulating organic film TFE2 may be disposed between the first encapsulating inorganic film TFE1 and the second encapsulating inorganic film TFE3. The encapsulation organic film TFE2 may be a monomer. Alternatively, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be from about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be from about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be from about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. In an embodiment where the cover layer CVL is a glass substrate, the cover layer CVL may be attached onto the filling layer FIL. In such an embodiment, the filling layer FIL may serve to bond the cover layer CVL. In an embodiment where the cover layer CVL is a glass substrate, the cover layer CVL may serve as an encapsulation substrate. In an embodiment where the cover layer CVL is a polymer resin, the cover layer CVL may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. In an embodiment, for example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of the display panel taken along line I1-I1′ shown in FIG. 7.

The embodiment of FIG. 10 is substantially the same as the embodiment of FIG. 9 except that the first electrode AND of each of the light emitting elements LE is in contact with and electrically connected to the side surface of a connection electrode ANC connected to the eighth conductive layer ML8, the trench TRC is omitted, and instead, the third pixel defining film PDL3 and a fourth pixel defining film PDL4 have an eave-shaped or mushroom-shaped cross-sectional structure. In description of the embodiment of FIG. 10, any repetitive detailed description of the same or like elements as those described above with reference to FIG. 9 will be omitted.

Referring to FIG. 10, in an embodiment, the plurality of connection electrodes ANC may be respectively disposed on first portions AA1 of the ninth interlayer insulating film INS9. Each of the plurality of connection electrodes ANC may be disposed on the first portion AA1 of the ninth interlayer insulating film INS9 corresponding thereto. A plurality of connection electrodes ANC may include or be formed of at least one selected from copper (Cu), aluminum (Al), tungsten (W), molybdenum (Mo), chromium (Cr), gold (Au), titanium (Ti), nickel (Ni), and neodymium (Nd), a combination (e.g., an alloy) thereof, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. For example, each of the plurality of reflective electrodes RL may include aluminum (Al) having high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may include or be formed of a silicon oxide (SiOx)-based inorganic film, but the present disclosure is not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary layer OAL are sequentially stacked, the first electrode AND of each of the light emitting elements LE may be disposed on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to a case where the first electrode AND of each of the light emitting elements LE is connected to the reflective electrode RL exposed through a through hole penetrating (defined or formed through) the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

Alternatively, the thickness of the first portion AA1 of the ninth interlayer insulating film INS9 may be greater than the thickness of the second portion AA2 thereof. In this case, the side surface of the first portion AA1 of the ninth interlayer insulating film INS9 may be exposed, and the first electrode AND of each of the light emitting elements LE may be disposed on the exposed side surface of the first portion AA1 of the ninth interlayer insulating film INS9.

The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), a combination (e.g., an alloy) thereof, or a transparent conductive oxide. For example, the first electrode AND of each of the light emitting elements LE may include titanium (Ti), titanium nitride (TiN), indium tin oxide (ITO), or indium zinc oxide (IZO), but the present disclosure is limited thereto.

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. In an embodiment, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth interlayer insulating film INS9.

The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In an embodiment, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may include or be formed of a silicon nitride (SiNx)-based inorganic film, whereas the second pixel defining film PDL2, the fourth pixel defining film PDL4, and the planarization film PNS may include or be formed of a silicon oxide (SiOx)-based inorganic film. In an embodiment, for example, the first pixel defining film PDL1 include or is formed of a material different from that of the planarization film PNS, and thus may serve as a stopper in a chemical mechanical polishing process for the planarization film PNS.

In an embodiment where the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an eaves-shaped or mushroom-shaped cross-sectional structure.

The light emitting stack IL may be disposed on the first electrode AND and the pixel defining film PDL. The light emitting stack IL may include the first stack layer IL1 and the second stack layer IL2 that emit different lights. In an embodiment where the light emitting stack IL has a two-tandem structure, one of the first stack layer IL1 and the second stack layer IL2 may emit light that includes the wavelength range of one of the first light, the second light, and the third light, and the other may emit light that includes the wavelength ranges of the other two lights. In an embodiment, for example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates an embodiment where the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to effectively prevent the light emitting stack IL in the adjacent emission areas EA1, EA2, and EA3 from emitting light other than the originally intended light due to the influence of the above current.

Although FIG. 10 illustrates an embodiment having a two-tandem structure in which the light emitting stack IL includes two stack layers IL1 and IL2, the present disclosure is not limited thereto. In another embodiment, for example, the light emitting stack IL may have a three-tandem structure including three stack layers as shown in FIG. 9. In such an embodiment, the charge generation layer between the first stack layer IL1 and the second stack layer IL2, and the charge generation layer between the second stack layer IL2 and the third stack layer IL3 may be cut off by adjusting the height of the third pixel defining film PDL3. Alternatively, as shown in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but the present disclosure is not limited thereto.

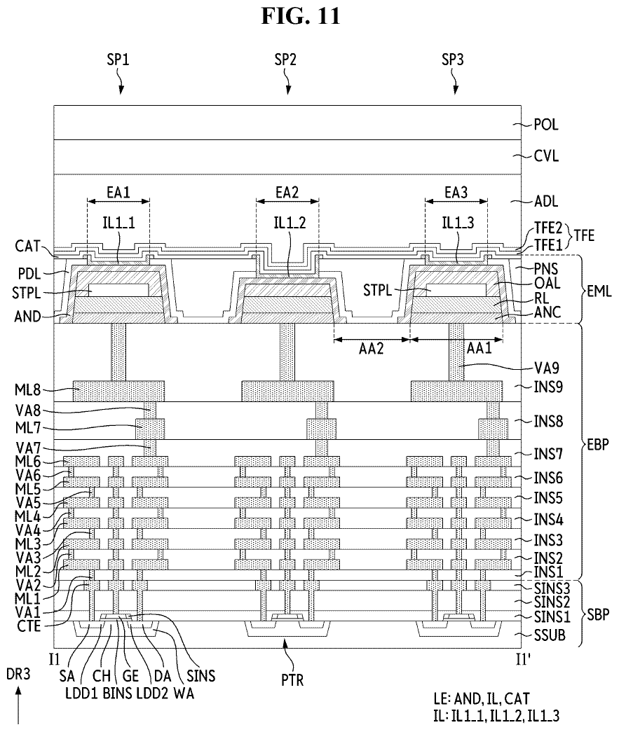

FIG. 11 is a schematic cross-sectional view illustrating still another example of the display panel taken along line I1-I1′ shown in FIG. 7.

The embodiment of FIG. 11 is substantially the same as the embodiment of FIG. 10 except that the light emitting elements LE have a single stack structure. In description of the embodiment of FIG. 11, any repetitive detailed description of the same or like elements as those described above with reference to FIG. 10 will be omitted.

Referring to FIG. 11, in an embodiment, the pixel defining film PDL may be disposed on the ninth interlayer insulating film INS9 and the first electrodes AND, and the planarization film PNS may be disposed on the pixel defining film PDL. The planarization film PNS and the pixel defining film PDL may be provided with openings exposing the first electrodes AND, and light emitting stack IL may be disposed on the first electrodes AND. For example, the pixel defining film PDL may be provided with openings exposing the first electrodes AND in the first light emission area EA1, the second light emission area EA2 and the third light emission area EA3, and the planarization film PNS may be provided with an opening exposing the first electrode AND in the second light emission area EA2. In an embodiment, for example, the light emitting stack IL may include a first stack layer IL1_1, a second stack layer IL1_2, and a third stack layer IL1_3.

The first stack layer IL1_1 may be disposed on the first electrode AND exposed by the pixel defining film PDL in the first light emission area EA1. The first stack layer IL1_1 may also be disposed on a portion of the pixel defining film PDL. In an embodiment, for example, the first stack layer IL1_1 may include a hole injecting layer, a hole transporting layer, a first light emitting layer, an electron transporting layer, and an electron injecting layer.

The second stack layer IL1_2 may be disposed on the first electrode AND exposed by the planarization film PNS and the pixel defining film PDL in the second light emission area EA2. The second stack layer IL1_2 may also be disposed on a portion of the planarization film PNS. In an embodiment, for example, the second stack layer IL1_2 may include the hole injecting layer, the hole transporting layer, a second light emitting layer, the electron transporting layer, and the electron injecting layer.

The third stack layer IL1_3 may be disposed on the first electrode AND exposed by the pixel defining film PDL in the third light emission area EA3. The third stack layer IL1_3 may also be disposed on a portion of the pixel defining film PDL. In an embodiment, for example, the third stack layer IL1_3 may include the hole injecting layer, the hole transporting layer, a third light emitting layer, the electron transporting layer, and the electron injecting layer.

The first stack layer IL1_1, the second stack layer IL1_2, and the third stack layer IL1_3 may be spaced apart from each other, and thus the second to fourth pixel defining films PDL2, PDL3 and PDL4 used to separate the light emitting stack IL in the embodiment of FIG. 10 may be omitted.

The first stack IL1_1 of the first light emission area EA1 may emit first light, the second stack layer IL1_2 of the second light emission area EA2 may emit second light, and the third stack layer IL1_3 of the third light emission area EA3 may emit third light. Accordingly, the first to third color filters CF1, CF2 and CF3 of the optical layer OPL used in the embodiment of FIG. 9, the plurality of lenses LNS, and the filling layer FIL may be omitted.

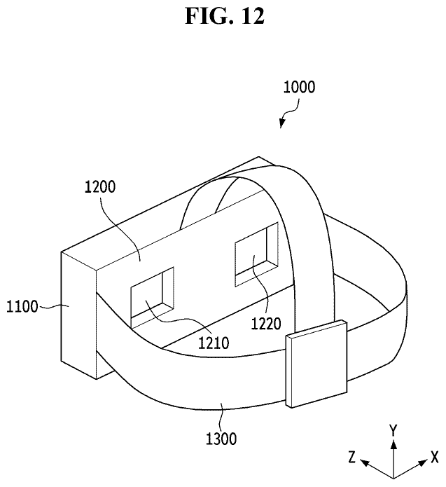

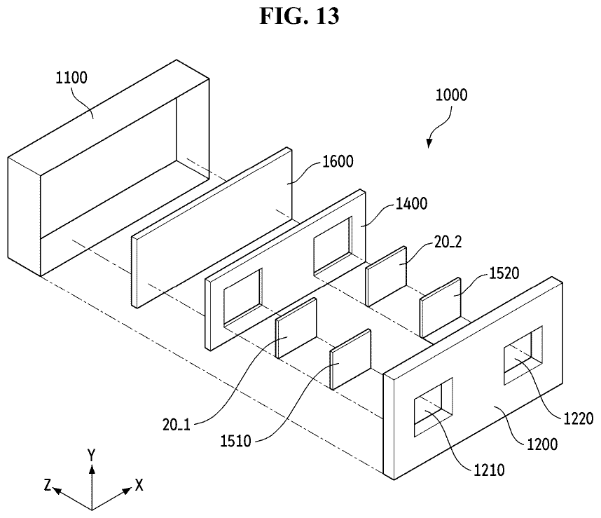

FIG. 12 is a schematic perspective view illustrating one example of a head mounted display. FIG. 13 is a schematic exploded perspective view illustrating the head mounted display shown in FIG. 12.

Referring to FIGS. 12 and 13, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 11, the description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data, and transmit the digital video data to the first display device 20_1 and the second display device 20_2 through the connector.

The control circuit board 1600 may transmit the digital video data corresponding to a left-eye image optimized for the user's left eye to the first display device 20_1, and may transmit the digital video data corresponding to a right-eye image optimized for the user's right eye to the second display device 20_2. Alternatively, the control circuit board 1600 may transmit the same digital video data to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 12 and 13 illustrate an embodiment where the first eyepiece 1210 and the second eyepiece 1220 are disposed or provided separately, but the present disclosure is not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

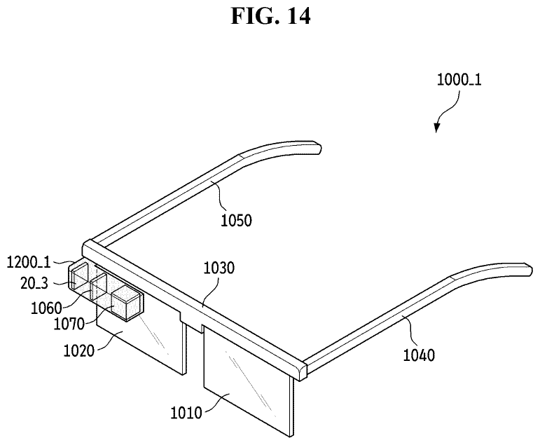

The head mounted band 1300 serves to secure the display device housing 1100 to the user's head such that the first eyepiece 1210 and the second eyepiece 1220 of the housing cover 1200 remain located on the user's left and right eyes, respectively. In an embodiment where the display device housing 1200 is desired to be implemented to be lightweight and compact, the head mounted display 1000 may be provided with, as shown in FIG. 14, an eyeglass frame instead of the head mounted band 1300.

FIG. 14 is a schematic perspective view illustrating another example of a head mounted display.

Referring to FIG. 14, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 14 illustrates an embodiment where the display device housing 1200_1 is disposed at the right end of the support frame 1030, but the present disclosure is not limited thereto. In another embodiment, for example, the display device housing 1200_1 may be disposed at the left end of the support frame 1030, and in such an embodiment, the image of the display device 20_3 may be provided to the user's left eye. Alternatively, the display device housing 1200_1 may be disposed at both the left and right ends of the support frame 1030, and in this case, the user may view the image displayed on the display device 20_3 through both the left and right eyes.

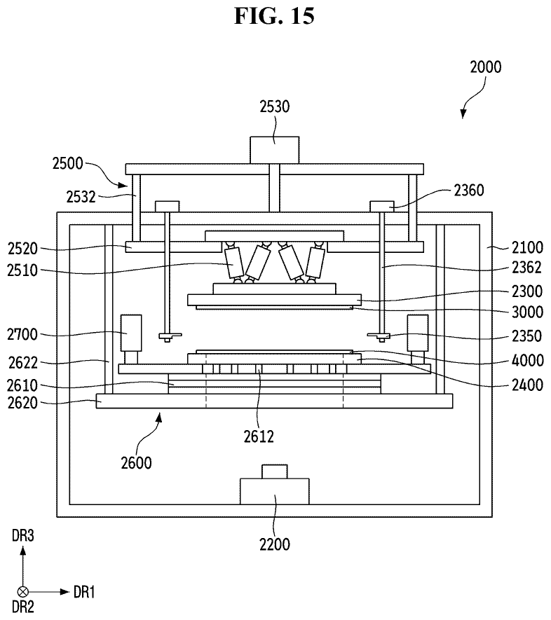

FIG. 15 is a schematic diagram illustrating a deposition mask and a deposition apparatus including the deposition mask according to an embodiment.

Referring to FIG. 15, a deposition apparatus 2000 according to an embodiment may be used to form a deposition material layer on a substrate. For example, the deposition apparatus 2000 according to an embodiment may be used to form light emitting layers on the backplane substrate 3000 (or display substrate) in a manufacturing process of the display panel 100 (see FIG. 3). In an embodiment, for example, as shown in FIG. 11, a semiconductor backplane SBP and a light emitting element backplane EBP may be disposed on the backplane substrate 3000, and electrode patterns, e.g., first electrodes AND functioning as anode electrodes, may be disposed on the light emitting element backplane EBP. In addition, a pixel defining film PDL provided with openings that expose the first electrodes AND may be disposed on the light emitting element backplane EBP. In an embodiment, for example, the deposition apparatus 2000 may form first light emitting layers on the first electrodes AND of the first emission areas EA1. In another embodiment, for example, the deposition apparatus 2000 may form second light emitting layers on the first electrodes AND of the second emission areas EA2. In another embodiment, for example, the deposition apparatus 2000 may form third light emitting layers on the first electrodes AND of the third emission areas EA3.

The deposition apparatus 2000 may include a deposition source 2200 for providing a vapor-phase deposition material on the backplane substrate 3000, a substrate chuck 2300 for supporting the backplane substrate 3000 to face the deposition source 2200, and a mask chuck 2400 disposed between the deposition source 2200 and the substrate chuck 2300 to support a deposition mask 4000 to face the backplane substrate 3000. The deposition source 2200, the substrate chuck 2300, and the mask chuck 2400 may be disposed in a process chamber (or an evaporation chamber) 2100.

A process chamber 2100 may define an internal space, and a deposition process for forming a deposition material layer on the backplane substrate 3000 may be performed in the internal space of the process chamber 2100. The process chamber 2100 may be connected to a vacuum pump (not shown), and a vacuum atmosphere may be created in the internal space of the process chamber 2100 by the vacuum pump. An opening (not shown) for loading/unloading of the backplane substrate 3000 and the deposition mask 4000 may be provided on one wall of the process chamber 2100, and the opening may be opened and closed by a gate valve (not shown).

The deposition source 2200 may be disposed in the process chamber 2100, and a deposition material may be stored in the deposition source 2200. The deposition source 2200 may evaporate a deposition material such as an organic material, an inorganic material, a conductive material, or the like toward the backplane substrate 3000, and the evaporated deposition material may be deposited on the backplane substrate 3000 through the deposition mask 4000. In an embodiment, for example, the deposition source 2200 may evaporate an organic light emitting material for forming light emitting layers on the backplane substrate 3000, and may be provided with a heater (not shown) for evaporating the organic light emitting material. The evaporated organic light emitting material may be deposited on electrode patterns on the backplane substrate 3000 through the deposition mask 4000, thereby forming light emitting layers on the electrode patterns of the backplane substrate 3000. In an embodiment, as shown in FIG. 15, the deposition source 2200 may be disposed on the central portion of the bottom surface of the process chamber 2100, but the deposition source 2200 may be configured to move horizontally by a separate driver (not shown).

The substrate chuck 2300 may be disposed above the deposition source 2200 and may support the backplane substrate 3000 such that the backplane substrate 3000 faces the deposition source 2200. In an embodiment, for example, the substrate chuck 2300 may be an electrostatic chuck that holds the rear surface of the backplane substrate 3000 using an electrostatic force. In an embodiment, the electrode patterns, e.g., first electrodes AND, may be disposed on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2350 for loading the backplane substrate 3000 onto the substrate chuck 2300 may be arranged in the process chamber 2100. The lift fingers 2350 may be arranged around the substrate chuck 2300 and the mask chuck 2400, and may be respectively moved vertically by finger drivers 2360. In an embodiment, for example, three or four lift fingers 2350 may be arranged around the substrate chuck 2300 and the mask chuck 2400, and may be moved in the third direction DR3 by the finger drivers 2360.

The backplane substrate 3000 may be loaded into the process chamber 2100 by a transfer robot (not shown), and may be transferred from the transfer robot onto the lift fingers 2350 under the substrate chuck 2300. In an embodiment, the rear surface of the backplane substrate 3000 may face the bottom surface of the substrate chuck 2300, and the lift fingers 2350 may support the front edge portions of the backplane substrate 3000. The finger drivers 2360 may raise the lift fingers 2350 such that the backplane substrate 3000 becomes adjacent to the bottom surface of the substrate chuck 2300, and the rear surface of the backplane substrate 3000 may be held on the bottom surface of the substrate chuck 2300 by an electrostatic force.

The finger drivers 2360 may be arranged on the upper lid of the process chamber 2100 and may be respectively connected to the lift fingers 2350 through driving shafts 2362 that extend vertically through the upper lid of the process chamber 2100. The finger drivers 2360 may vertically move the lift fingers 2350 to load or unload the backplane substrate 3000. In addition, the finger drivers 2360 may rotate the lift fingers 2350 with respect to each of the driving shafts 2362. In an embodiment, for example, the finger drivers 2360 may rotate the lift fingers 2350 such that the ends of the lift fingers 2350 do not overlap the substrate chuck 2300 and the mask chuck 2400, thereby enabling vertical movement of the lift fingers 2350. In addition, the finger drivers 2360 may rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot, and may be transferred onto the lift fingers 2350 above the mask chuck 2400. The edge portions of the deposition mask 4000 may be placed on the ends of the lift fingers 2350, and the finger drivers 2360 may lower the lift fingers 2350 to load the deposition mask 4000 onto the mask chuck 2400. In an embodiment, recesses (not shown) into which ends of lift fingers 2350 are inserted may be provided at the edge portions of the mask chuck 2400, and the finger drivers 2360 may rotate the lift fingers 2350 such that the lift fingers 2350 do not overlap the mask chuck 2400 after the deposition mask 4000 is loaded on the mask chuck 2400.

The mask chuck 2400 may support the edge portion of the deposition mask 4000. For example, the mask chuck 2400 may be an electrostatic chuck configured to hold the edge portion of the deposition mask 4000 using an electrostatic force. In particular, the mask chuck 2400 may be provided with a circular opening to expose the deposition mask 4000 toward the deposition source 2200. In an embodiment, for example, the mask chuck 2400 may have a disk shape or a quadrilateral plate shape with a circular opening.

The deposition apparatus 2000 may include a chuck driver for adjusting the position and posture of the backplane substrate 3000 and the deposition mask 4000. In an embodiment, for example, the deposition apparatus 2000 may include a substrate chuck driver 2500 for moving the substrate chuck 2300 and a mask chuck driver 2600 for moving the mask chuck 2400.

In an embodiment, the substrate chuck driver 2500 may move the substrate chuck 2300 in the first direction DR1, the second direction DR2, and the third direction DR3 to adjust the position of the backplane substrate 3000. In this case, the first direction DR1 may be the first horizontal direction, the second direction DR2 may be the second horizontal direction perpendicular to the first direction DR1, and the third direction DR3 may be the vertical direction. For example, the first direction DR1, the second direction DR2, and the third direction DR3 may be an X-axis direction, a Y-axis direction, and a Z-axis direction, respectively.

The substrate chuck driver 2500 may rotate the substrate chuck 2300 around the Z-axis to adjust the azimuth of the backplane substrate 3000, that is, the angle at which the backplane substrate 3000 is held on the bottom surface of the substrate chuck 2300. Further, the substrate chuck driver 2500 may rotate the substrate chuck 2300 around the X-axis, and may also rotate the substrate chuck 2300 around the Y-axis in order to adjust the inclination of the backplane substrate 3000. In an embodiment, for example, the substrate chuck driver 2500 may include a hexapod actuator 2510 that provides a motion of six degrees of freedom (X, Y, Z, θx, θy, and θz).

The substrate chuck driver 2500 may include a substrate stage 2520 to which the hexapod actuator 2510 is mounted, and a second actuator 2530 connected to the substrate stage 2520. The substrate stage 2520 may be disposed horizontally in the process chamber 2100, and the second actuator 2530 may be disposed above the process chamber 2100. The second actuator 2530 may be connected to the substrate stage 2520 by a plurality of driving shafts 2532 extending in the third direction DR3, i.e., the vertical direction (Z-axis direction) through the upper lid of the process chamber 2100, and may move the substrate stage 2520 in the central axis direction of the hexapod actuator 2510, i.e., the vertical direction. In an embodiment, for example, the second actuator 2530 may be configured using a brushless direct current (DC) motor, a linear motor, a direct drive (DD) motor, or the like, and may adjust the height of the substrate chuck 2300 for loading or unloading the backplane substrate 3000.

The hexapod actuator 2510 may include a first platform connected to the substrate chuck 2300, a second platform mounted to the substrate stage 2520, and six sub-actuators disposed between the first platform and the second platform. In an embodiment, for example, the six sub-actuators may each be configured using a brushless DC motor, a voice coil linear motor, a step motor, a DD motor, a servo motor, or the like, and may move and rotate the first platform to adjust the horizontal position, vertical position, azimuth, and inclination of the backplane substrate 3000.

The mask chuck driver 2600 may move and rotate the mask chuck 2400 to adjust the horizontal position of the deposition mask 4000 and the azimuth angle of the deposition mask 4000, that is, the angle at which the deposition mask 4000 is placed on the mask chuck 2400. The mask chuck driver 2600 may move the mask chuck 2400 in a direction parallel to the deposition mask 4000 and rotate the mask chuck 2400 with respect to the central axis of the mask chuck 2400. In an embodiment, for example, the mask chuck driver 2600 may move the mask chuck 2400 in the first direction DR1 (X-axis) and the second direction DR2 (Y-axis), and may rotate the mask chuck 2400 with respect to the third direction DR3 (Z-axis).

The mask chuck driver 2600 may include, e.g., a piezo actuator 2610 that provides a motion of three degrees of freedom (X, Y, and Oz). The piezo actuator 2610 may have an opening communicating with the circular opening of the mask chuck 2400. The mask chuck 2400 may be spaced upward from the piezo actuator 2610 by a selected distance. In an embodiment, for example, a plurality of support members 2612 may be arranged on the piezo actuator 2610, and the mask chuck 2400 may be disposed on the plurality of support members 2612.

The mask chuck driver 2600 may include a mask stage 2620 that is horizontally disposed in the process chamber 2100 and supports the piezo actuator 2610. In an embodiment, for example, the mask stage 2620 may have an opening that communicates with the opening of the piezo actuator 2610 and may be supported by a plurality of posts 2622 that are connected to the upper lid of the process chamber 2100.

After the backplane substrate 3000 and the deposition mask 4000 are loaded onto the substrate chuck 2300 and the mask chuck 2400, respectively, the second actuator 2530 may lower the substrate chuck 2300 such that the backplane substrate 3000 is brought adjacent to the deposition mask 4000. The hexapod actuator 2510 may adjust the gap between the backplane substrate 3000 and the deposition mask 4000, and may adjust the inclination of the substrate chuck 2300 to adjust the parallelism between the substrate chuck 2300 and the mask chuck 2400. In an embodiment, for example, although not shown, a plurality of gap sensors (not shown) for measuring the gap between the substrate chuck 2300 and the mask chuck 2400 may be mounted at the substrate chuck 2300, and the hexapod actuator 2510 may adjust the parallelism between the substrate chuck 2300 and the mask chuck 2400 based on the measured values of the gap sensors.

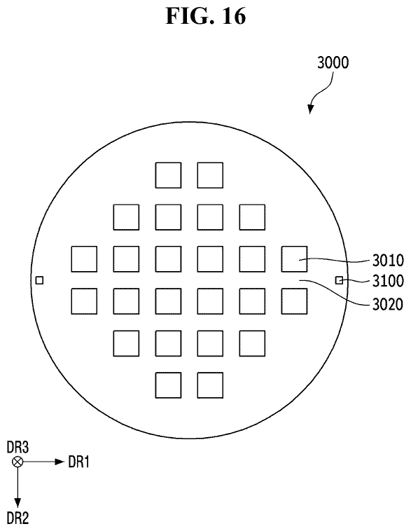

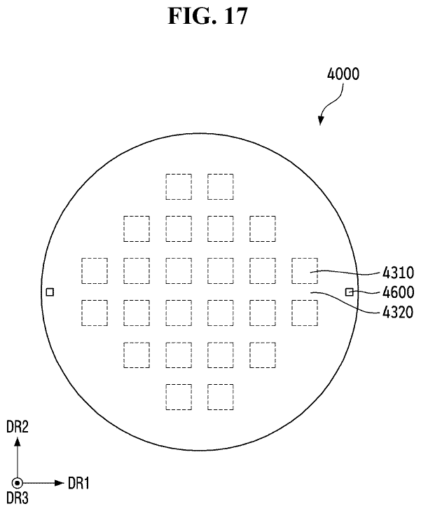

The deposition apparatus 2000 may include cameras 2700 for acquiring positional information of the backplane substrate 3000 and the deposition mask 4000 for alignment between the backplane substrate 3000 and the deposition mask 4000. In an embodiment, for example, substrate alignment keys 3100 (see FIG. 16) may be arranged on the edge portions of the backplane substrate 3000, and mask alignment keys 4600 (see FIG. 17) may be arranged on the edge portions of the deposition mask 4000. The deposition apparatus 2000 may include the cameras 2700 for detecting the substrate alignment keys 3100 and the mask alignment keys 4600, and the substrate chuck driver 2500 or the mask chuck driver 2600 may align the backplane substrate 3000 and the deposition mask 4000 with each other based on the positional information of the substrate alignment keys 3100 and the mask alignment keys 4600 obtained by the cameras 2700.

As described above, after the parallelism adjustment between the substrate chuck 2300 and the mask chuck 2400 and the positional alignment between the backplane substrate 3000 and the deposition mask 4000 are performed, the backplane substrate 3000 may be positioned on the deposition mask 4000. In an embodiment, for example, the hexapod actuator 2510 may adjust the height of the substrate chuck 2300 such that the gap between the backplane substrate 3000 and the deposition mask 4000 becomes a selected gap, e.g., a gap of several μm. In another embodiment, for example, the hexapod actuator 2510 may adjust the height of the substrate chuck 2300 such that the backplane substrate 3000 is brought into contact with the deposition mask 4000.

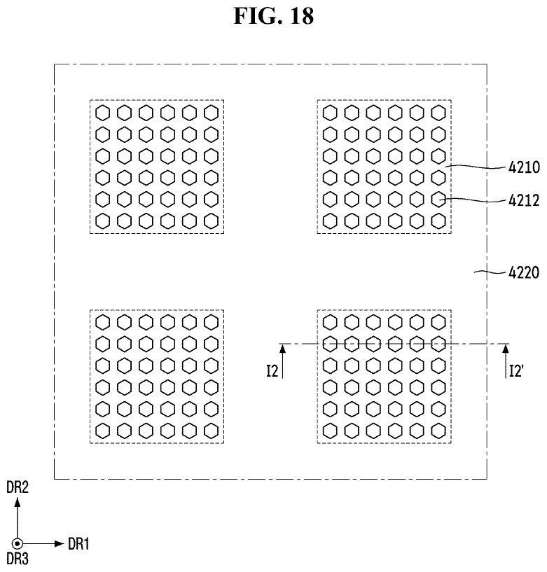

After the backplane substrate 3000 is positioned on the deposition mask 4000, the deposition source 2200 may provide a vapor-phase deposition material onto the backplane substrate 3000 through the deposition mask 4000, thereby forming a deposition material layer on the backplane substrate 3000. In an embodiment, for example, the deposition source 2200 may provide a vapor light emitting material for forming light emitting layers on the backplane substrate 3000, and the vapor light emitting material may be deposited on the electrode patterns of the backplane substrate 3000 through pixel openings 4212 (see FIG. 18) of the deposition mask 4000.

FIG. 16 is a schematic bottom view illustrating the backplane substrate shown in FIG. 15.

Referring to FIG. 16, the backplane substrate 3000 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 16, and may be individualized into the display panels 100 (see FIG. 3) by a dicing process after the display manufacturing process is completed. In an embodiment, for example, the first direction DR1 may be a first horizontal direction, and the second direction DR2 may be a second horizontal direction perpendicular to the first direction DR1. In addition, each of the display cell regions 3010 may have, for example, a quadrilateral shape as shown in the drawing.

In an embodiment, for example, each of the display cell regions 3010 may include the semiconductor backplane SBP and the light emitting element backplane EBP disposed on the semiconductor backplane SBP, as shown in FIG. 11. In addition, a plurality of electrode patterns, e.g., the plurality of first electrodes AND may be disposed on the light emitting element backplane EBP, and the pixel defining film PDL having openings that expose the first electrodes AND may be disposed on the light emitting element backplane EBP and the first electrodes AND. In such an embodiment, the electrode patterns of the display cell regions 3010 may be arranged on the front surface of the backplane substrate 3000, and the substrate chuck 2300 may hold the rear surface of the backplane substrate 3000 such that the electrode patterns of the display cell regions 3010 face downward, i.e., face the deposition source 2200.

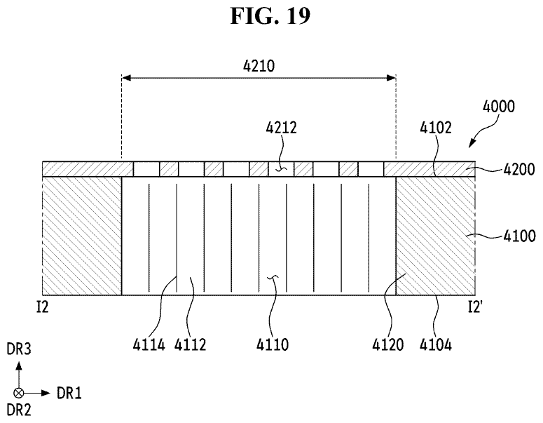

FIG. 17 is a schematic plan view illustrating the deposition mask shown in FIG. 15. FIG. 18 is a schematic enlarged plan view illustrating the mask cell regions shown in FIG. 17. FIG. 19 is a schematic cross-sectional view taken along line 12-12′ shown in FIG. 18.

Referring to FIGS. 17 to 19, an embodiment of the deposition mask 4000 may include mask cell regions 4210 respectively corresponding to the display cell regions 3010 of the backplane substrate 3000, and a grid region 4220 corresponding to the scribe lane region 3020 of the backplane substrate 3000. Each of the mask cell regions 4210 may have the plurality of pixel openings 4212 corresponding to the electrode patterns of each of the display cell regions 3010. In an embodiment, for example, when the backplane substrate 3000 is positioned above the deposition mask 4000, the electrode patterns, e.g., the first electrodes AND, of the backplane substrate 3000 may be positioned above the pixel openings 4212, and accordingly, the first electrodes AND may be exposed toward the deposition source 2200 through the pixel openings 4212.

According to an embodiment, the deposition mask 4000 may include a mask substrate 4100 and the membrane 4200 disposed on the mask substrate 4100. In such an embodiment, the membrane 4200 may include the plurality of mask cell regions 4210 and the grid region 4220 disposed between the mask cell regions 4210, and each of the mask cell regions 4210 may have the plurality of pixel openings 4212.

The mask substrate 4100 may be provided with cell openings 4110 respectively corresponding to the mask cell regions 4210, and may include a rib region 4120 defining the cell openings 4110. According to an embodiment, the mask cell regions 4210 of the membrane 4200 may be regions exposed through the cell openings 4110 of the mask substrate 4100, and the grid region 4220 of the membrane 4200 may be disposed on the rib region 4120 of the mask substrate 4100. The pixel openings 4212 may be formed to penetrate the mask cell regions 4210, and may communicate with the cell openings 4110. In an embodiment, the vapor-phase deposition material provided from the deposition source 2200 may be deposited on the first electrodes AND of the backplane substrate 3000 through the cell openings 4110 and the pixel openings 4212.

In an embodiment, as shown in FIG. 17, the mask cell regions 4210 may be arranged in a matrix form along the first direction DR1 and the second direction DR2. In an embodiment, for example, the first direction DR1 may be the first horizontal direction, and the second direction DR2 may be the second horizontal direction perpendicular to the first direction DR1. The mask cell regions 4210 may have, for example, a quadrilateral shape as shown in the drawing, and the pixel openings 4212 may be arranged to correspond to the first electrodes AND of any of the first emission areas EA1, the second emission areas EA2, and the third emission areas EA3.

The mask substrate 4100 may include single crystal silicon. In an embodiment, for example, a single crystal silicon substrate having a thickness in a range of about 700 μm to about 800 μm, e.g., about 775 μm, may be used as the mask substrate 4100. The membrane 4200 may include an inorganic material, e.g., silicon nitride (SiNx), and may be formed on a front surface 4102 of the mask substrate 4100 to have a thickness in a range of about 0.3 μm to about 3 μm through a chemical vapor deposition (CVD) process.

According to an embodiment, inner side surfaces 4112 of the mask substrate 4100 defining the cell openings 4110 may have a stripe-shaped surface profile 4114 extending in the thickness direction of the mask substrate 4100, e.g., in the third direction DR3. In an embodiment, for example, the cell openings 4110 may be formed by a metal assisted chemical etching (MACE) process using a metal catalyst material such as gold (Au), silver (Ag), platinum (Pt), or palladium (Pd), and during the MACE process, the stripe-shaped surface profile 4114 including regularly spaced, stripe-like regions extending in the third direction DR3 may be formed on the inner side surfaces 4112 of the mask substrate 4100 defining the cell openings 4110.

According to an embodiment, the cell openings 4110 may be formed substantially perpendicular to a rear surface 4104 of the mask substrate 4100 by the MACE process. In an embodiment, for example, the inner side surfaces 4112 of the mask substrate 4100 defining the cell openings 4110 may be perpendicular to the rear surface 4104 of the mask substrate 4100 or have an inclination angle of about 85° or greater with respect to the rear surface 4104 of the mask substrate 4100. Therefore, compared to a conventional deposition mask, the cross-sectional area of the rib region 4120 that defines the cell openings 4110 may be increased and the rigidity of the mask substrate 4100 may be increased. As a result, the structural stability of the deposition mask 4000 may be improved, thereby reducing the warpage of the deposition mask 4000.

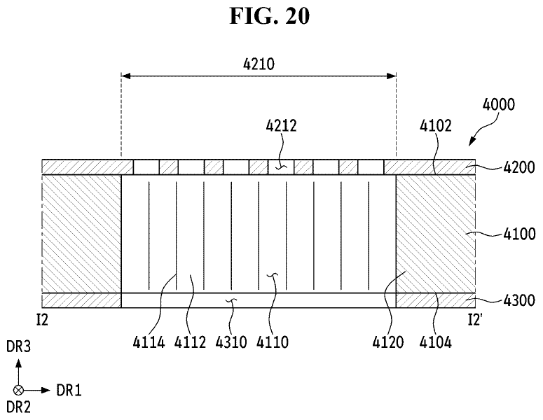

FIG. 20 is a schematic cross-sectional view illustrating another example of the deposition mask shown in FIG. 19.

Referring to FIG. 20, an embodiment of the deposition mask 4000 may include a rear inorganic film 4300 disposed on the rear surface 4104 of the mask substrate 4100. According to an embodiment, the rear inorganic film 4300 may be used to reduce the warpage of the deposition mask 4000. The rear inorganic film 4300 may have a residual stress similar to that of the membrane 4200, and may be used to offset a force applied to the mask substrate 4100 by the residual stress of the membrane 4200. In an embodiment, for example, the rear inorganic film 4300 may include silicon nitride (SiNx), and may be formed with a thickness in a range of about 0.3 μm to about 3 μm on the rear surface 4104 of the mask substrate 4100 by a CVD process. In an embodiment, for example, the rear inorganic film 4300 may be formed simultaneously with the membrane 4200 through a CVD process, and accordingly, the rear inorganic film 4300 and the membrane 4200 may include a same material and have a same thickness as each other.

According to an embodiment, the rear inorganic film 4300 may be provided with rear openings 4310 that expose the cell openings 4110, that is, communicate with the cell openings 4110. In an embodiment, for example, the cell openings 4110 and the rear openings 4310 may have substantially a same width as each other, and the cell openings 4110 may be disposed above the rear openings 4310. In such an embodiment, the vapor-phase deposition material provided from the deposition source 2200 may be deposited on the first electrodes AND of the backplane substrate 3000 through the rear openings 4310, the cell openings 4110, and the pixel openings 4212.

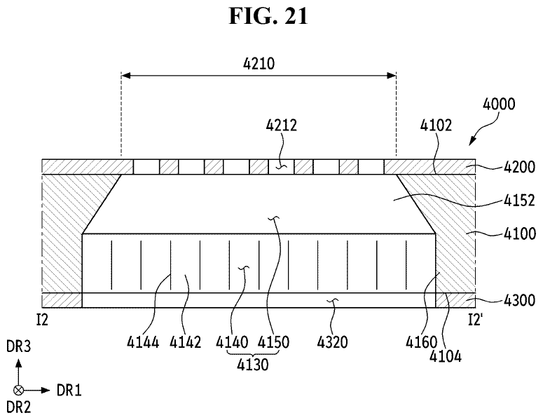

FIG. 21 is a schematic cross-sectional view illustrating still another example of the deposition mask shown in FIG. 19.

Referring to FIG. 21, an embodiment of the deposition mask 4000 may include the mask substrate 4100, the membrane 4200, and the rear inorganic film 4300. The membrane 4200 may be disposed on the front surface 4102 of the mask substrate 4100 and may include the mask cell regions 4210 with the plurality of pixel openings 4212. The mask substrate 4100 may be provided with cell openings 4130 exposing the mask cell regions 4210, and may include a rib region 4160 defining the cell openings 4130. The rear inorganic film 4300 may be disposed on the rear surface 4104 of the mask substrate 4100 and may have rear openings 4320 that expose the cell openings 4130.

According to an embodiment, each of the cell openings 4130 may include a first opening 4140 adjacent to the rear inorganic film 4300 and a second opening 4150 adjacent to the membrane 4200. The first opening 4140 may extend in the thickness direction of the mask substrate 4100, e.g., in the third direction DR3, and may have a substantially constant width. In addition, the width of the first opening 4140 may be substantially the same as the width of the rear opening 4320. The second opening 4150 may connect the first opening 4140 to the pixel openings 4212, and may have a width that gradually decreases in a direction from the first opening 4140 toward the mask cell region 4210.

In an embodiment, for example, the first opening 4140 may be formed through a MACE process, and accordingly, a stripe-shaped surface profile 4144 extending in the thickness direction of the mask substrate 4100 may be formed or defined on inner side surface portions 4142 of the mask substrate 4100 defining the first opening 4140. In addition, the inner side surface portions 4142 of the mask substrate 4100 defining the first opening 4140 may be perpendicular to the rear surface 4104 of the mask substrate 4100 or have an inclination angle of about 85° or greater with respect to the rear surface 4104 of the mask substrate 4100. Accordingly, compared to a conventional deposition mask, the cross-sectional area of the rib region 4160 that defines the cell openings 4130 may be increased and the rigidity of the mask substrate 4100 may be increased. As a result, the structural stability of the deposition mask 4000 may be improved, thereby reducing the warpage of the deposition mask.

In an embodiment, for example, the second opening 4150 may be formed by a wet etching process using an etching solution such as a TMAH solution, a KOH solution, or an EDP solution, and accordingly, the second opening 4150 may have a width that gradually decreases in a direction from the first opening 4140 toward the membrane 4200. In an embodiment, for example, the <100> crystal direction of the single crystal silicon substrate used as the mask substrate 4100 may be the third direction DR3, and accordingly, inner side surface portions 4152 of the mask substrate 4100 defining the second opening 4150 may have an inclination angle of about 54.7° with respect to the rear surface 4104 of the mask substrate 4100.

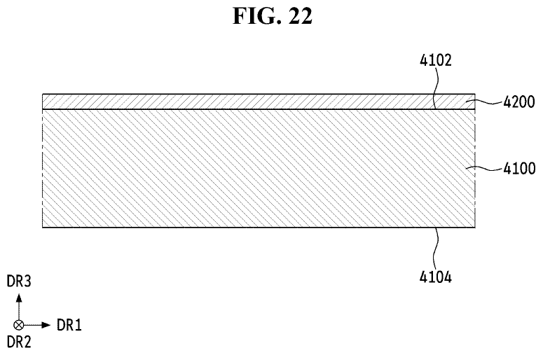

FIGS. 22 to 27 are schematic cross-sectional views illustrating a method of manufacturing a deposition mask according to an embodiment of the present disclosure.

Referring to FIG. 22, in an embodiment of a method of manufacturing a deposition mask, the membrane 4200 may be formed on the mask substrate 4100. In an embodiment, for example, the mask substrate 4100 may have the front surface 4102 and the rear surface 4104, and the membrane 4200 may be formed on the front surface 4102 of the mask substrate 4100. According to an embodiment, the mask substrate 4100 may include single crystal silicon. In an embodiment, for example, a single crystal silicon substrate having a thickness in a range of about 700 μm to about 800 μm, e.g., about 775 μm, may be used as the mask substrate 4100.

According to an embodiment, the membrane 4200 may include an inorganic material, e.g., silicon nitride (SiNx), and may be formed on the front surface 4102 of the mask substrate 4100 through a CVD process. In an embodiment, for example, a silicon source gas such as monosilane (SiH₄), disilane (Si₂H₆), or dichlorosilane (DCS) (SiH₂Cl₂), and a nitrogen source gas such as nitrogen (N₂) or ammonia (NH₃) may be supplied onto the mask substrate 4100, and the membrane 4200 may be formed with a thickness of about 0.3 μm to about 3 μm on the front surface 4102 of the mask substrate 4100 by a reaction between the silicon source gas and the nitrogen source gas.

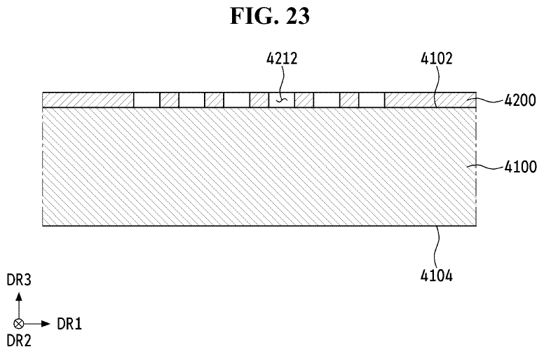

Referring to FIG. 23, in an embodiment of a method of manufacturing a deposition mask, the membrane 4200 may be patterned to form the pixel openings 4212 that penetrate the membrane 4200. According to an embodiment, the membrane 4200 may be partially removed by an anisotropic etching process, thereby forming the pixel openings 4212 that penetrate the membrane 4200. In an embodiment, for example, a photoresist pattern (not shown) that exposes portions where the pixel openings 4212 are to be formed may be formed on the membrane 4200, and an anisotropic etching process, e.g., a reactive ion etching (RIE) process may be performed using the photoresist pattern as an etching mask.

In an embodiment, for example, where the membrane 4200 includes silicon nitride (SiNx), the RIE process may be performed using a first reactive gas, such as CF₄, C₂F₄, C₂F₆, C₃F₆, C₃F₈, C₄F₆, C₄F₈, CH₃F, CH₂F₂, C₂HF₅, CHF₃, NF₃, or SF₆, containing fluorine, a second reactive gas, such as O₂, NO, or NO₂, containing oxygen, and a sputtering gas, such as He, Ne, Ar, or Xe, until the mask substrate 4100 is exposed, thereby forming the pixel openings 4212 penetrating the membrane 4200. The photoresist pattern may be removed by an ashing and/or strip process after the pixel openings 4212 are formed.

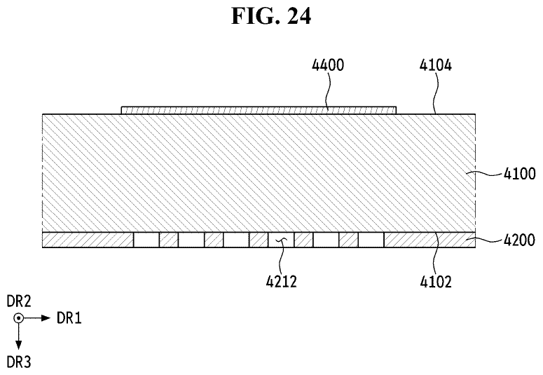

Referring to FIGS. 24 to 27, in an embodiment of a method of manufacturing a deposition mask, the mask substrate 4100 may be patterned to form the cell openings 4110 that expose the pixel openings 4212. According to an embodiment, the cell opening 4110 may be formed by a MACE process. In an embodiment, for example, the cell openings 4110 may be formed by forming a metal catalyst pattern 4400 on the rear surface 4104 of the mask substrate 4100, and performing a wet etching process using an etching solution containing hydrogen peroxide (H₂O₂) and hydrofluoric acid (HF). In such an embodiment, silicon of the mask substrate 4100 may be etched at an interface between the metal catalyst pattern 4400 and the mask substrate 4100, and the silicon etching may be continuously performed by mass transfer of reactants and products through pinholes of the metal catalyst pattern 4400.

According to an embodiment, as shown in FIG. 24, the metal catalyst pattern 4400 may be formed on the rear surface 4104 of the mask substrate 4100. In an embodiment, for example, a metal catalyst layer (not shown) may be formed on the rear surface 4104 of the mask substrate 4100. In an embodiment, for example, the metal catalyst layer may contain gold (Au), silver (Ag), platinum (Pt), palladium (Pd), or the like and may be formed through a physical vapor deposition (PVD) process such as a thermal evaporation process, an electron beam evaporation process, or a sputtering process. Subsequently, the metal catalyst layer may be patterned to form the metal catalyst pattern 4400 on the rear surface 4104 of the mask substrate 4100. In an embodiment, for example, after forming a photoresist pattern (not shown) that exposes portions except for a portion where the metal catalyst pattern 4400 is to be formed on the metal catalyst layer, an etching process may be performed using the photoresist pattern as an etching mask, thereby forming the metal catalyst pattern 4400 on the rear surface 4104 of the mask substrate 4100.

In another embodiment, for example, after forming a photoresist pattern (not shown) that exposes a portion where the metal catalyst pattern 4400 is to be formed on the rear surface 4104 of the mask substrate 4100, the metal catalyst layer may be formed, and then the photoresist pattern may be removed to form the metal catalyst pattern 4400 on the rear surface 4104 of the mask substrate 4100.

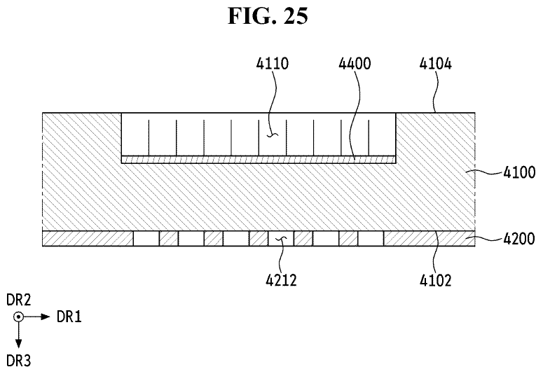

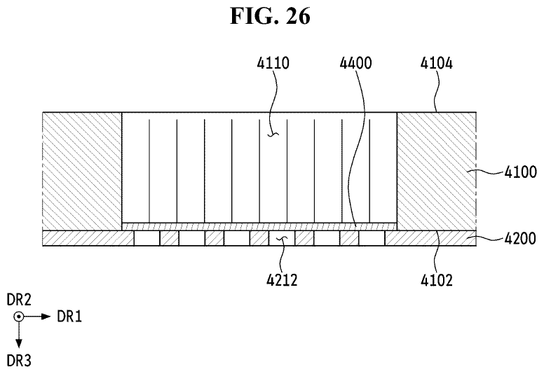

After forming the metal catalyst pattern 4400, the mask substrate 4100 may be partially removed through a wet etching process using an etching solution containing hydrogen peroxide (H₂O₂) and hydrofluoric acid (HF), thereby forming the cell opening 4110 that penetrates the mask substrate 4100 as shown in FIGS. 25 and 26. According to an embodiment, in the wet etching process, the metal catalyst pattern 4400 may function as both a catalyst and a cathode, and hydrogen peroxide (H₂O₂) may be reduced by the metal catalyst pattern 4400 to generate holes, as expressed in the following reaction formula (1):

$${H}_{2} {O}_{2} + 2 {H}^{+} \to 2 {H}_{2} O + 2 {h}^{+} \qquad ( 1 )$$

The holes may be diffused through the metal catalyst pattern 4400 and injected into the mask substrate 4100. In this case, the mask substrate 4100 may function as an anode, and the silicon of the mask substrate 4100 may be oxidized by the injected holes and dissolved at the interface between the metal catalyst pattern 4400 and the mask substrate 4100 by hydrofluoric acid (HF), as expressed in the following reaction formula (2):

$$Si + 4 {h}^{+} + 6 HF \to {SiF}_{6}^{2 -} + 6 {H}^{+} \qquad ( 2 )$$

Hydrogen peroxide (H₂O₂) may be used as an oxidizing agent in the wet etching process. In an embodiment, for example, the concentration of hydrogen peroxide (H₂O₂) may be about 0.2 M to about 0.8 M. Hydrofluoric acid (HF) may be used as an etchant in the wet etching process. In an embodiment, for example, the concentration of hydrofluoric acid (HF) may be about 5 M to about 8 M. Water, ethanol, or a mixed solution of water and ethanol may be used as a solvent.

In other embodiments, for example, silver nitrate (AgNO₃), chloroauric acid (HAuCl₄), chloroplatinic acid (H₂PtCl₆), iron (III) nitrate (Fe(NO₃)₃), nickel (II) nitrate (Ni(NO₃)₂), magnesium nitrate (Mg(NO₃)₂), sodium persulfate (Na₂S₂O₈), potassium permanganate (KMnO₄), potassium dichromate (K₂Cr₂O₇), and the like may be used as oxidizing agents.

In the wet etching process, reactants and products may be transferred through the pinholes of the metal catalyst pattern 4400, and may diffuse along the interface between the metal catalyst pattern 4400 and the mask substrate 4100. According to an embodiment, silicon etching may be continuously performed at the interface between the metal catalyst pattern 4400 and the mask substrate 4100, thereby causing the metal catalyst pattern 4400 to move in the thickness direction of the mask substrate 4100, e.g., in the third direction DR3 as shown in FIGS. 25 and 26. In addition, the stripe-shaped surface profile 4114 extending in the third direction DR3 may be formed on the inner side surfaces 4112 of the mask substrate 4100 defining the cell opening 4110 by the movement of the metal catalyst pattern 4400.

According to an embodiment, the pinholes of the metal catalyst pattern 4400 have a density of about 100 per μm² to about 300 per μm². In such an embodiment, the metal catalyst pattern 4400 may be formed to have a thickness in a range of about 3 nm to about 10 nm to allow the pinholes of the metal catalyst pattern 4400 to have a density of about 100 per μm² to about 300 per μm². When the thickness of the metal catalyst pattern 4400 is less than 3 nm, the density of the pinholes may excessively increase, and when the thickness of the metal catalyst pattern 4400 is greater than 10 nm, the density of the pinholes may significantly decrease. When the density of the pinholes is excessively high or low, the etching rate of the mask substrate 4100 may be lowered. For example, when the thickness of the metal catalyst pattern 4400 is about 3 nm to about 10 nm, the etching rate of the mask substrate 4100 may be about 0.2 μm/min to about 0.45 μm/min. In addition, for example, when the thickness of the metal catalyst pattern 4400 is about 5 nm, the etching rate of the mask substrate 4100 may be about 0.4 μm/min or greater.

According to an embodiment, the metal catalyst pattern 4400 may include gold (Au), silver (Ag), platinum (Pt), palladium (Pd), or the like. According to an embodiment, the metal catalyst pattern 4400 may have a single-layer structure or a double-layer structure. In an embodiment, for example, a gold (Au) single-layer pattern or a silver (Ag) single-layer pattern may be used as the metal catalyst pattern 4400. In another embodiment, for example, a gold/silver (Au/Ag) double-layer pattern may be used as the metal catalyst pattern 4400. In such an embodiment, the silver (Ag) pattern layer may function as an adhesive layer between the mask substrate 4100 and the gold (Au) pattern layer.

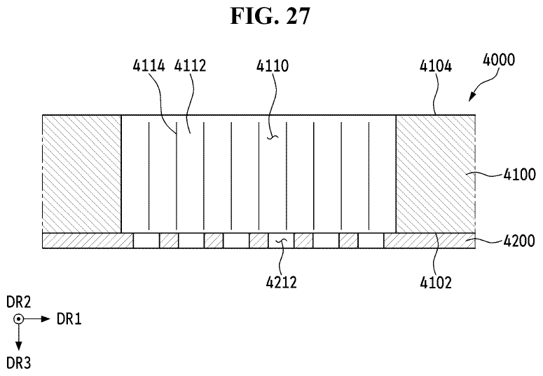

As shown in FIG. 26, the MACE process may be performed until the metal catalyst pattern 4400 reaches the membrane 4200, thereby forming the cell opening 4110 that penetrates the mask substrate 4100. According to an embodiment, after forming the cell opening 4110 through the MACE process, the metal catalyst pattern 4400 may be removed as shown in FIG. 27. In an embodiment, for example, the metal catalyst pattern 4400 may be removed by a wet etching process. In an embodiment where the metal catalyst pattern 4400 includes gold (Au) or platinum (Pt), the metal catalyst pattern 4400 may be removed using an etching solution containing hydrochloric acid (HCl) and nitric acid (HNO₃). In another embodiment where the metal catalyst pattern 4400 includes silver (Ag), the metal catalyst pattern 4400 may be removed using an etching solution containing phosphoric acid (H₃PO₄) and nitric acid (HNO₃).

Although not shown in the drawings, after the metal catalyst pattern 4400 is removed, silicon residues (not shown) may remain on the rear surface of the membrane 4200. In an embodiment, for example, a silicon portion between the metal catalyst pattern 4400 and the membrane 4200 may not be completely removed by the MACE process, and accordingly, silicon residues may remain on the rear surface of the membrane 4200. In this case, a wet etching process for removing the silicon residues may be additionally performed. In an embodiment, for example, a wet etching process may be performed using an etching solution such as a TMAH solution, a KOH solution, or an EDP solution, thereby removing the silicon residues.

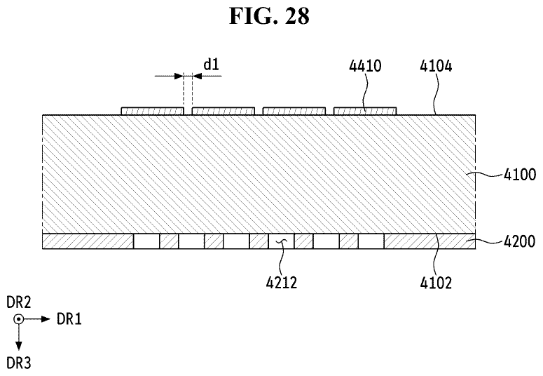

FIGS. 28 to 30 are schematic views illustrating a method of manufacturing a deposition mask according to another embodiment of the present disclosure.

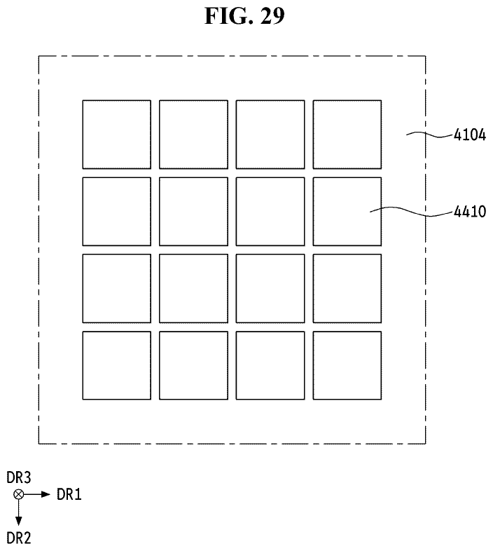

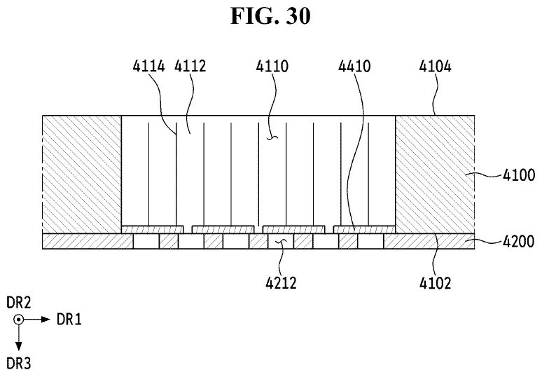

FIG. 28 is a schematic cross-sectional view illustrating metal catalyst patterns formed on a rear surface of a mask substrate. FIG. 29 is a schematic plan view illustrating metal catalyst patterns shown in FIG. 28. FIG. 30 is a schematic cross-sectional view illustrating a cell opening formed by metal catalyst patterns shown in FIG. 28.

Referring to FIGS. 28 to 30, in an embodiment of a method of manufacturing a deposition mask, after forming the membrane 4200 with the plurality of pixel openings 4212 on the front surface 4102 of the mask substrate 4100, a MACE process may be performed to form the cell opening 4110. In an embodiment, for example, a plurality of metal catalyst patterns 4410 may be formed on the rear surface 4104 of the mask substrate 4100, and the cell opening 4110 that penetrates the mask substrate 4100 may be formed by a wet etching process using an etching solution containing hydrogen peroxide (H₂O₂) and hydrofluoric acid (HF). Such an embodiment is substantially the same as the embodiment described above with reference to FIGS. 22 to 27 except that the cell opening 4110 is formed using the plurality of metal catalyst patterns 4410. In description of such an embodiment, any repetitive detailed descriptions of the same or like elements as those described above with reference to FIGS. 22 to 27 will be omitted.

Referring to FIGS. 28 and 29, in an embodiment of a method of manufacturing a deposition mask, the plurality of metal catalyst patterns 4410 may be formed on the rear surface 4104 of the mask substrate 4100. According to an embodiment, in order to facilitate the transfer of reactants and products in the wet etching process, the metal catalyst patterns 4410 may be spaced apart at selected intervals, and the transfer of reactants and products may be performed between the metal catalyst patterns 4410. In an embodiment, for example, a gap d1 between the metal catalyst patterns 4410 may be in a range from about 0.01 μm to about 1 μm, and silicon portions between the metal catalyst patterns 4410 may be removed by a MACE process. According to an embodiment, holes generated by reduction of hydrogen peroxide (H₂O₂) may be injected into the mask substrate 4100 through the metal catalyst patterns 4410, and some of the injected holes may be diffused into the silicon portions between the metal catalyst patterns 4410. The silicon portions between the metal catalyst patterns 4410 may be oxidized by the diffused holes, and may be dissolved and removed by hydrofluoric acid (HF).

According to an embodiment, the metal catalyst patterns 4410 may each have a quadrilateral shape, and may be arranged in a matrix form along the first direction DR1 and the second direction DR2. As shown in the drawings, sixteen metal catalyst patterns 4410 are used, but the size and number of the metal catalyst patterns 4410 may be changed, and accordingly, the scope of the present disclosure is not limited by the size and number of the metal catalyst patterns 4410. In an embodiment, for example, although not shown in the drawings, the metal catalyst patterns 4410 may each have a hexagonal shape and may be arranged in a honeycomb configuration. In another embodiment, for example, the metal catalyst patterns 4410 may each have a rod shape extending in the first direction DR1 or the second direction DR2, and may be arranged in the second direction DR2 or the first direction DR1.

Referring to FIG. 30, in an embodiment of a method of manufacturing a deposition mask, after forming the metal catalyst patterns 4410, a wet etching process may be performed using an etching solution containing hydrogen peroxide (H₂O₂) and hydrofluoric acid (HF), thereby forming the cell opening 4110 that penetrates the mask substrate 4100. While forming the cell opening 4110, the metal catalyst patterns 4410 may be moved in the third direction DR3, and accordingly, the stripe-shaped surface profile 4114 extending in the third direction DR3 may be formed on the inner side surfaces 4112 of the mask substrate 4100 defining the cell opening 4110.

After the MACE process is performed, the metal catalyst patterns 4410 may be removed by a wet etching process using a metal etchant such as hydrochloric acid (HCl), phosphoric acid (H₃PO₄), or nitric acid (HNO₃), and accordingly, the manufacture of the deposition mask 4000 as shown in FIG. 27 may be completed. After the metal catalyst patterns 4410 are removed, silicon residues may remain on the rear surface of the membrane 4200. In an embodiment, for example, the silicon portions between the metal catalyst patterns 4410 and the membrane 4200 and the silicon portions between the metal catalyst patterns 4410 may not be completely removed by the MACE process, and accordingly, silicon residues may remain on the rear surface of the membrane 4200. In such an embodiment, a wet etching process for removing the silicon residues may be additionally performed. In an embodiment, for example, a wet etching process may be performed using an etching solution such as a TMAH solution, a KOH solution, or an EDP solution, thereby removing the silicon residues.

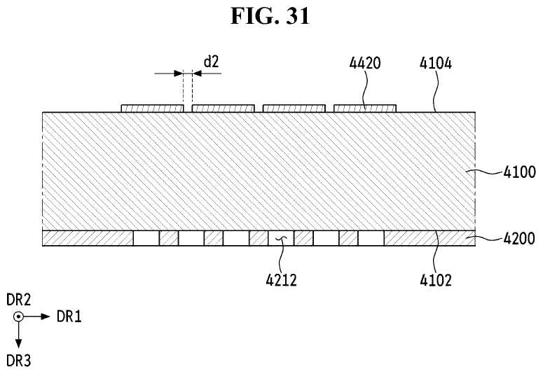

FIGS. 31 to 33 are schematic cross-sectional views illustrating a method of manufacturing a deposition mask according to still another embodiment of the present disclosure.

Referring to FIGS. 31 to 33, in an embodiment of a method of manufacturing a deposition mask, after forming the membrane 4200 with the plurality of pixel openings 4212 on the front surface 4102 of the mask substrate 4100, a MACE process may be performed to form the cell opening 4110. In an embodiment, for example, a plurality of metal catalyst patterns 4420 may be formed on the rear surface 4104 of the mask substrate 4100, and the cell opening 4110 that penetrates the mask substrate 4100 may be formed by a wet etching process using an etching solution containing hydrogen peroxide (H₂O₂) and hydrofluoric acid (HF). Such an embodiment is substantially the same as the embodiment described above with reference to FIGS. 22 to 27 except that the cell opening 4110 is formed using the plurality of metal catalyst patterns 4420 and a gap d2 between the metal catalyst patterns 4420 is relatively large. In description of such an embodiment, any repetitive detailed descriptions of the same or like elements as those described above with reference to FIGS. 22 to 30 will be omitted.

Referring to FIG. 31, in an embodiment of a method of manufacturing a deposition mask, the plurality of metal catalyst patterns 4420 may be formed on the rear surface 4104 of the mask substrate 4100. The plurality of metal catalyst patterns 4420 may be spaced apart at selected intervals. According to an embodiment, the gap d2 between the metal catalyst patterns 4420 may be in a range from about 1 μm to about 20 μm. When the gap d2 between the metal catalyst patterns 4420 is less than about 1 μm, the metal catalyst patterns 4420 are likely to be connected to each other during the MACE process, and when the gap d2 between the metal catalyst patterns 4420 is greater than about 20 μm, the cell opening 4110 may be excessively expanded while removing residual silicon portions (partition walls) 4430 remaining between the metal catalyst patterns 4420 after the MACE process is performed.

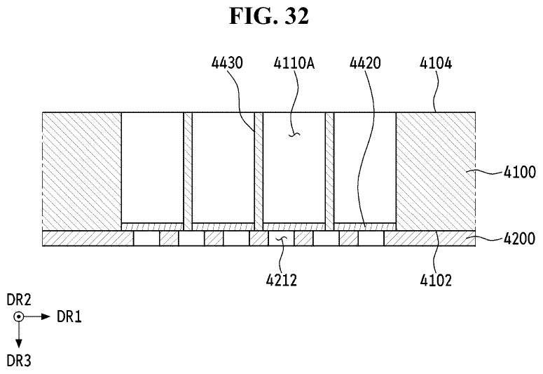

Referring to FIG. 32, in an embodiment of a method of manufacturing a deposition mask, after the metal catalyst patterns 4420 are formed, a wet etching process may be performed using an etching solution containing hydrogen peroxide (H₂O₂) and hydrofluoric acid (HF), thereby forming a plurality of preliminary cell openings 4110A that penetrate the mask substrate 4100. While forming the preliminary cell openings 4110A, the metal catalyst patterns 4420 may be moved in the third direction DR3, and accordingly, the silicon partition walls 4430 may be formed between the metal catalyst patterns 4420, i.e., between the preliminary cell openings 4110A. In such an embodiment, the preliminary cell openings 4110A may be defined by the partition walls 4430.

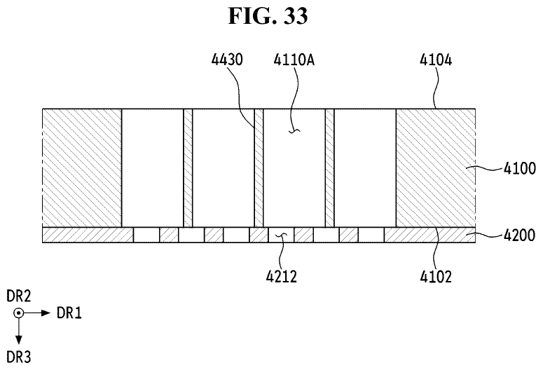

Referring to FIG. 33, in an embodiment of a method of manufacturing a deposition mask, after the MACE process is performed, the metal catalyst patterns 4420 may be removed by a wet etching process using a metal etchant such as hydrochloric acid (HCl), phosphoric acid (H₃PO₄), or nitric acid (HNO₃). Subsequently, the silicon partition walls 4430 between the preliminary cell openings 4410A may be removed by a wet etching process, and accordingly, as shown in FIG. 27, the cell opening 4110 that exposes the pixel openings 4212 may be formed. In an embodiment, for example, a wet etching process may be performed using an etching solution such as a TMAH solution, a KOH solution, or an EDP solution, thereby removing the silicon partition walls 4430. In addition, while removing the silicon partition walls 4430, silicon residues remaining on the rear surface of the membrane 4200 may be removed together. In this case, the width of the cell opening 4110 may be slightly expanded.

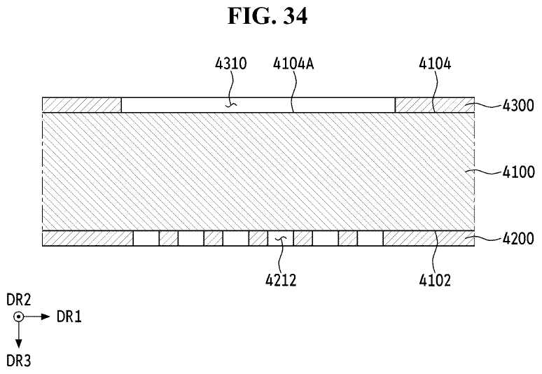

FIGS. 34 to 37 are schematic cross-sectional views illustrating a method of manufacturing a deposition mask according to still another embodiment of the present disclosure.

Referring to FIGS. 34 to 37, in an embodiment of a method of manufacturing a deposition mask, the rear inorganic film 4300 with the rear opening 4310 may be formed on the rear surface 4104 of the mask substrate 4100. Subsequently, the MACE process may be performed to form the cell opening 4110 that connects the pixel openings 4212 to the rear opening 4310. Such an embodiment is substantially the same as the embodiment described above with reference to FIGS. 22 to 27 except that the rear inorganic film 4300 is formed on the rear surface 4104 of the mask substrate 4100. In description of such an embodiment, any repetitive detailed descriptions of the same or like elements as those described above with reference to FIGS. 22 to 27 will be omitted.

Referring to FIG. 34, in an embodiment of a method of manufacturing a deposition mask, the rear inorganic film 4300 may be formed on the rear surface 4104 of the mask substrate 4100. According to an embodiment, the rear inorganic film 4300 may be formed on the rear surface 4104 of the mask substrate 4100 to have a thickness of about 0.3 μm to about 3 μm by a CVD process. In an embodiment, for example, a silicon source gas such as monosilane (SiH₄), disilane (Si₂H₆), or dichlorosilane (DCS) (SiH₂Cl₂), and a nitrogen source gas such as nitrogen (N₂) or ammonia (NH₃) may be supplied onto the rear surface 4104 of the mask substrate 4100, and the rear inorganic film 4300 may be formed with a thickness in a range of about 0.3 μm to about 3 μm on the rear surface 4104 of the mask substrate 4100 by a reaction between the silicon source gas and the nitrogen source gas.

Subsequently, the rear inorganic film 4300 may be patterned to form the rear opening 4310 that penetrates the rear inorganic film 4300 and partially exposes the rear surface 4104 of the mask substrate 4100. According to an embodiment, the rear inorganic film 4300 may be partially removed by an anisotropic etching process, thereby forming the rear opening 4310 that penetrates the rear inorganic film 4300. In an embodiment, for example, a photoresist pattern (not shown) that exposes a portion where the rear opening 4310 is to be formed may be formed on the rear inorganic film 4300, and an anisotropic etching process, e.g., an RIE process, may be performed using the photoresist pattern as an etching mask.

In an embodiment where the rear inorganic film 4300 includes silicon nitride (SiNx), the RIE process may be performed using a first reactive gas, such as CF₄, C₂F₄, C₂F₆, C₃F₆, C₃F₈, C₄F₆, C₄F₈, CH₃F, CH₂F₂, C₂HF₅, CHF₃, NF₃, or SF₆, containing fluorine, a second reactive gas, such as O₂, NO, or NO₂, containing oxygen, and a sputtering gas, such as He, Ne, Ar, or Xe, until the rear surface 4104 of the mask substrate 4100 is exposed, thereby forming the rear opening 4310 penetrating the rear inorganic film 4300. The photoresist pattern may be removed by an ashing and/or stripping process after the rear opening 4310 is formed.

According to an embodiment, the rear inorganic film 4300 may be formed simultaneously with the membrane 4200 through a CVD process. In such an embodiment, the rear opening 4310 may be formed after the pixel openings 4212 that penetrate the membrane 4200 are formed. In another embodiment, for example, the pixel openings 4212 may be formed after forming the rear opening 4310.

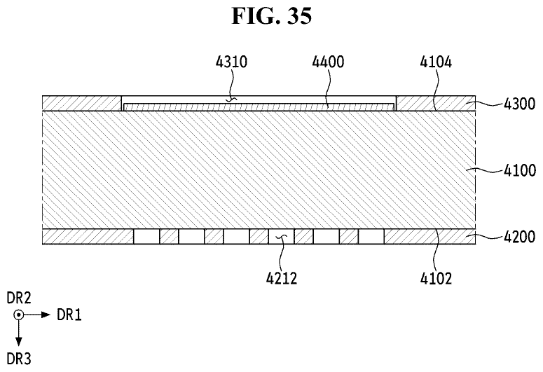

Referring to FIG. 35, in an embodiment of a method of manufacturing a deposition mask, the metal catalyst pattern 4400 may be formed on a rear portion 4104A (see FIG. 34) of the mask substrate 4100 exposed through the rear opening 4310. According to an embodiment, a metal catalyst layer (not shown) may be formed on the rear inorganic film 4300 and the exposed rear portion 4104A of the mask substrate 4100, and then the metal catalyst layer may be patterned to form the metal catalyst pattern 4400 on the exposed rear portion 4104A of the mask substrate 4100. In another embodiment, for example, after forming a photoresist pattern (not shown) that exposes a portion where the metal catalyst pattern 4400 is to be formed, the metal catalyst pattern 4400 may be formed on the portion exposed by the photoresist pattern. In such an embodiment, a method of forming the metal catalyst pattern 4400 may be substantially the same as the method described above with reference to FIG. 24, and thus any repetitive detailed description of the method of forming the metal catalyst pattern 4400 will be omitted.

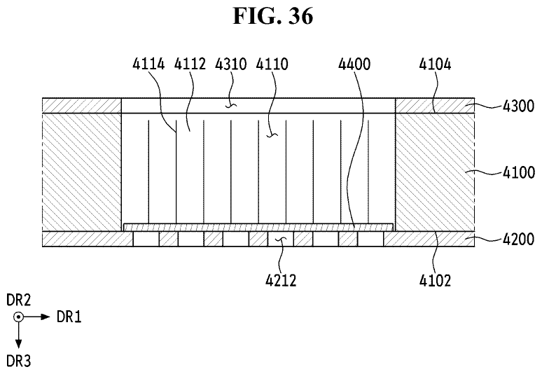

Referring to FIG. 36, in an embodiment of a method of manufacturing a deposition mask, the cell opening 4110 that penetrates the mask substrate 4100 may be formed by performing a MACE process using the metal catalyst pattern 4400. In an embodiment, for example, after forming the metal catalyst pattern 4400, a wet etching process may be performed using an etching solution containing hydrogen peroxide (H₂O₂) and hydrofluoric acid (HF). While forming the cell opening 4110, the metal catalyst pattern 4400 may be moved in the third direction DR3, and accordingly, the stripe-shaped surface profile 4114 extending in the third direction DR3 may be formed on the inner side surfaces 4112 of the mask substrate 4100 defining the cell opening 4110.

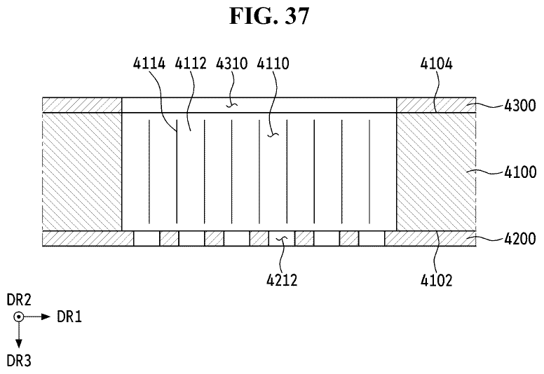

Referring to FIG. 37, in an embodiment of a method of manufacturing a deposition mask, after the MACE process is performed, the metal catalyst pattern 4400 may be removed by a wet etching process using a metal etchant such as hydrochloric acid (HCl), phosphoric acid (H₃PO₄), or nitric acid (HNO₃). Furthermore, a wet etching process for removing silicon residues remaining on the rear surface of the membrane 4200 may be additionally performed. In an embodiment, for example, a wet etching process may be performed using an etching solution such as a TMAH solution, a KOH solution, or an EDP solution, thereby removing the silicon residues.

According to still another embodiment of the present disclosure, although not shown in the drawings, a plurality of metal catalyst patterns (not shown) may be formed on the rear portion 4104A of the mask substrate 4100 exposed through the rear opening 4310, and the cell opening 4110 may be formed by a MACE process using the metal catalyst patterns. A method of forming the cell opening 4110 using the metal catalyst patterns may be substantially the same as the embodiments described above with reference to FIGS. 28 to 33, and thus any repetitive detailed description of the method of forming the cell opening using the metal catalyst patterns will be omitted.

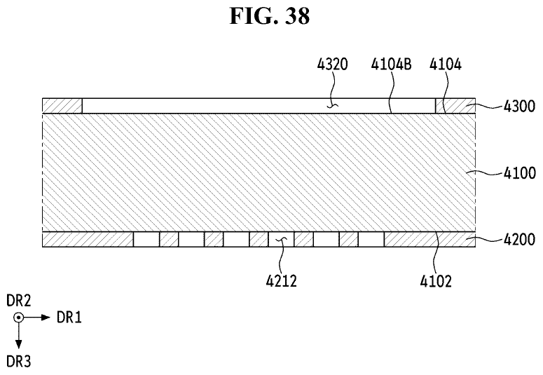

FIGS. 38 to 45 are schematic cross-sectional views illustrating a method of manufacturing a deposition mask according to still another embodiment of the present disclosure.

Referring to FIGS. 38 to 45, in an embodiment of a method of manufacturing a deposition mask, the cell opening 4130 may include the first opening 4140 adjacent to the rear inorganic film 4300 and the second opening 4150 adjacent to the membrane 4200. Such an embodiment is substantially the same as the embodiment described above with reference to FIGS. 22 to 27 except that the rear inorganic film 4300 is formed on the rear surface 4104 of the mask substrate 4100, and the cell opening 4130 includes the first opening 4140 and the second opening 4150. In description of such an embodiment, any repetitive detailed descriptions of the same or like elements as those described above with reference to FIGS. 22 to 27 and 34 to 37 will be omitted.

Referring to FIG. 38, in an embodiment of a method of manufacturing a deposition mask, the membrane 4200 may be formed on the front surface 4102 of the mask substrate 4100, and the membrane 4200 may be patterned to form the plurality of pixel openings 4212. In addition, the rear inorganic film 4300 may be formed on the rear surface 4104 of the mask substrate 4100, and the rear inorganic film 4300 may be patterned to form the rear opening 4320.

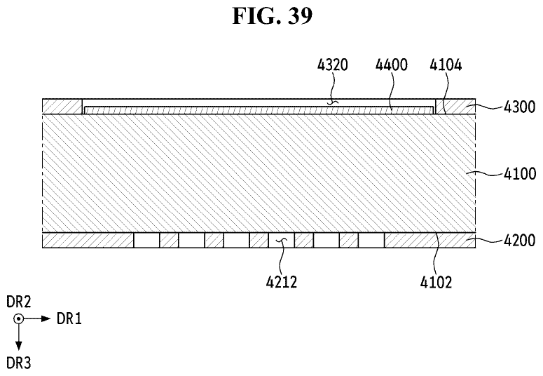

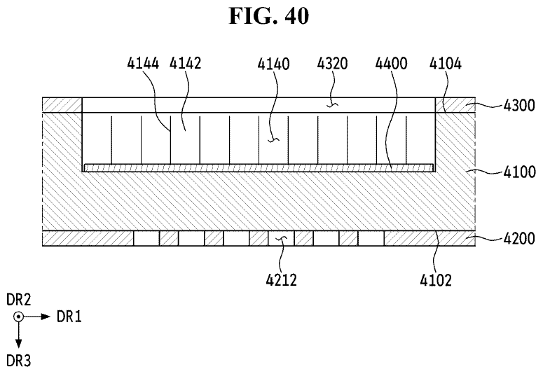

Referring to FIGS. 39 and 40, in an embodiment of a method of manufacturing a deposition mask, a metal catalyst pattern 4440 may be formed on a rear portion 4104B (see FIG. 38) of the mask substrate 4100 exposed through the rear opening 4320. Subsequently, by performing a MACE process using the metal catalyst pattern 4440, the first opening 4140 extending from the rear surface 4104 of the mask substrate 4100 toward the front surface 4102 of the mask substrate 4100 may be formed. According to an embodiment, while forming the first opening 4140, the metal catalyst pattern 4440 may be moved in the third direction DR3, and accordingly, the stripe-shaped surface profile 4144 extending in the third direction DR3 may be formed on the inner side surfaces 4142 of the first opening 4140.

According to an embodiment, the depth of the first opening 4140 may be about 300 μm to about 700 μm. According to an embodiment, the width of the rear opening 4320 may be greater than that of the rear opening 4310 shown in FIGS. 34 to 37, and the width of the first opening 4140 may be greater than that of the cell opening 4110 shown in FIGS. 36 and 37. In addition, the width of the metal catalyst pattern 4440 may be greater than that of the metal catalyst pattern 4400 shown in FIGS. 35 and 36. According to an embodiment, by forming the rear opening 4320, the first opening 4140, and the metal catalyst pattern 4440 relatively larger than those of the embodiments described above with reference to FIGS. 34 to 37, alignment between the cell opening 4130 and the pixel openings 4212 may be facilitated.

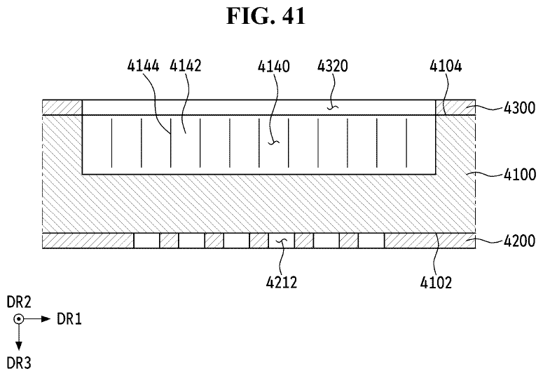

Referring to FIG. 41, in an embodiment of a method of manufacturing a deposition mask, after forming the first opening 4140, the metal catalyst pattern 4440 may be removed. For example, the metal catalyst pattern 4440 may be removed by a wet etching process using a metal etchant such as hydrochloric acid (HCl), phosphoric acid (H₃PO₄), or nitric acid (HNO₃).

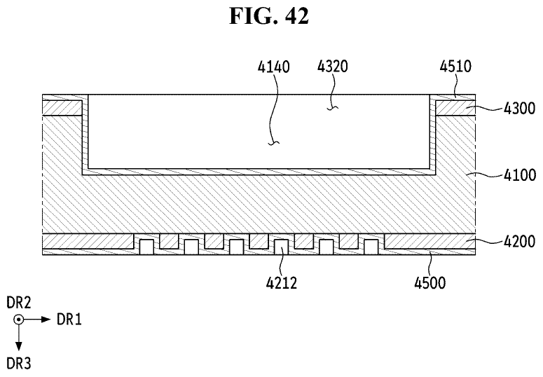

Referring to FIG. 42, in an embodiment of a method of manufacturing a deposition mask, a front passivation film 4500 may be formed on the membrane 4200 and the inner surfaces of the pixel openings 4212. In an embodiment, for example, the front passivation film 4500 may include silicon oxide (SiOx), and may be formed to have a thickness in a range of about 0.2 μm to about 2 μm by a CVD process. According to an embodiment, a rear passivation film 4510 may be formed on the rear inorganic film 4300 and the inner surfaces of the first opening 4140 and the rear opening 4320. In an embodiment, for example, the rear passivation film 4510 may include silicon oxide (SiOx), and may be formed to have a thickness in a range of about 0.2 μm to about 2 μm by a CVD process.

According to an embodiment, the front passivation film 4500 and the rear passivation film 4510 may be simultaneously formed by a CVD process. In an embodiment, for example, a silicon source gas such as monosilane (SiH₄), disilane (Si₂H₆), or dichlorosilane (DCS) (SiH₂Cl₂), and an oxygen source gas such as oxygen (O₂), nitrous oxide (N₂O), or nitric oxide (NO) may be supplied onto the mask substrate 4100, and the front passivation film 4500 and the rear passivation film 4510 may be formed by a reaction between the silicon source gas and the oxygen source gas.

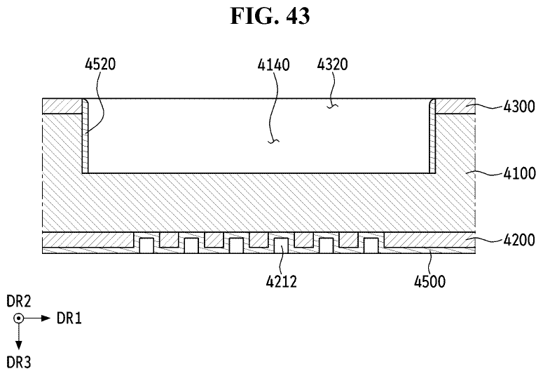

Referring to FIG. 43, in an embodiment of a method of manufacturing a deposition mask, the rear passivation film 4510 may be partially removed to form a liner pattern 4520 on inner side surfaces of the first opening 4140. According to an embodiment, an anisotropic etching process, e.g., an RIE process, may be performed to remove a portion of the rear passivation film 4510 on the rear inorganic film 4300 and a portion of the rear passivation film 4510 on the bottom surface of the first opening 4140, thereby forming the liner pattern 4520 on the inner side surfaces of the first opening 4140. In an embodiment, for example, the RIE process may be performed until the bottom surface of the first opening 4140 is exposed using a reaction gas containing fluorine, such as CF₄, C₂F₄, C₂F₆, C₃F₆, C₃F₈, C₄F₆, C₄F₈, CH₃F, CH₂F₂, C₂HF₅, CHF₃, NF₃, SF₆, or the like, and a sputtering gas, such as He, Ne, Ar, Xe, or the like.

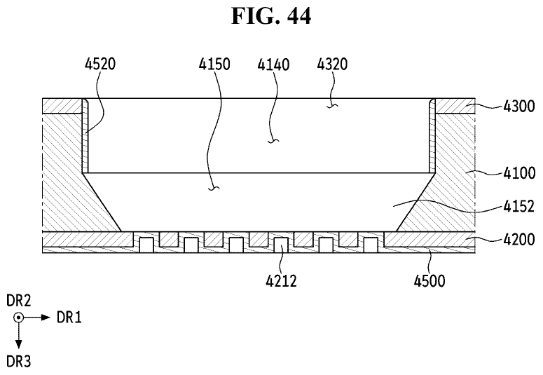

Referring to FIG. 44, in an embodiment of a method of manufacturing a deposition mask, the mask substrate 4100 may be partially removed to form the second opening 4150 that connects the first opening 4140 to the pixel openings 4212 of the membrane 4200. According to an embodiment, a wet etching process may be performed using an etching solution such as a TMAH solution, a KOH solution, or an EDP solution, thereby forming the second opening 4150 that connects the first opening 4140 to the pixel openings 4212 of the membrane 4200. In an embodiment, for example, the wet etching process may be performed until the rear surface of the membrane 4200 is exposed, and the front passivation film 4500, the rear inorganic film 4300, and the liner pattern 4520 may function as etching masks.

According to an embodiment, the <100> crystal direction of the single crystal silicon substrate used as the mask substrate 4100 may be the third direction DR3, and accordingly, the second opening 4150 may have a width that gradually decreases in a direction from the first opening 4140 toward the membrane 4200. In an embodiment, for example, the inner side surface portions 4152 of the mask substrate 4100 defining the second opening 4150 may have an inclination angle of about 54.7° with respect to the rear surface 4104 of the mask substrate 4100.

According to an embodiment, while forming the second opening 4150, hydrogen (H₂) bubbles may be generated by a reaction between the mask substrate 4100 and the etching solution. For example, if the front passivation film 4500 is omitted, an etching solution may be provided onto the front surface 4102 of the mask substrate 4100 through the pixel openings 4212, thereby generating hydrogen (H₂) bubbles in the pixel openings 4212. In this case, the membrane 4200 may be damaged by the hydrogen (H₂) bubbles, and the front passivation film 4500 may be used to prevent the etching solution from being provided onto the front surface 4102 of the mask substrate 4100 through the pixel openings 4212.

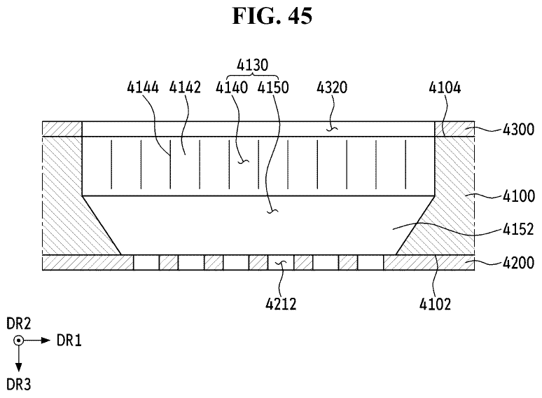

Referring to FIG. 45, in an embodiment of a method of manufacturing a deposition mask, the front passivation film 4500 and the liner pattern 4520 may be removed, and accordingly, the pixel openings 4212 may communicate with the second opening 4150 of the cell opening 4130. In an embodiment where the front passivation film 4500 and the liner pattern 4520 include silicon oxide (SiOx), the front passivation film 4500 and the liner pattern 4520 may be formed by a wet etching process using an etching solution such as buffered oxide etchant (BOE) or diluted HF.

According to still another embodiment of the present disclosure, although not shown in the drawings, a plurality of metal catalyst patterns (not shown) may be formed on the rear portion 4104B of the mask substrate 4100 exposed through the rear opening 4320, and the first opening 4140 may be formed by a MACE process using the metal catalyst patterns. A method of forming the first opening 4140 using the metal catalyst patterns may be substantially the same as the method of forming the cell opening 4110 in the embodiments described above with reference to FIGS. 28 to 33, and thus any repetitive detailed description of the method of forming the first opening 4140 using the metal catalyst patterns will be omitted.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate provided with a cell opening; and
a membrane disposed on a front surface of the mask substrate and provided with a plurality of pixel openings communicating with the cell opening,
wherein an inner side surface of the mask substrate defining the cell opening has a stripe-shaped surface profile extending in a thickness direction of the mask substrate.

2. A method of manufacturing a deposition mask, the method comprising:
forming a membrane with a plurality of pixel openings on a front surface of a mask substrate; and
forming a cell opening communicating with the pixel openings through the mask substrate by partially removing a portion of the mask substrate,
wherein an inner side surface of the mask substrate defining the cell opening has a stripe-shaped surface profile extending in a thickness direction of the mask substrate.

3. The method of claim 2, wherein the forming the cell opening comprises:
forming a metal catalyst pattern on a rear surface of the mask substrate; and
performing a metal assisted chemical etching process on the mask substrate using the metal catalyst pattern to form the cell opening.

4. The method of claim 3, wherein in the performing the metal assisted chemical etching process, the metal catalyst pattern is moved in the thickness direction of the mask substrate, and
the stripe-shaped surface profile is formed while the metal catalyst pattern is moved.

5. The method of claim 3, wherein the forming the cell opening further comprises:
removing the metal catalyst pattern after the performing the metal assisted chemical etching process.

6. The method of claim 3, wherein the forming the cell opening further comprises:
removing etching residues after the performing the metal assisted chemical etching process.

7. The method of claim 2, wherein the forming the cell opening comprises:
forming a plurality of metal catalyst patterns on a rear surface of the mask substrate; and
performing a metal assisted chemical etching process on the mask substrate using the metal catalyst patterns to form the cell opening.

8. The method of claim 2, wherein the forming the cell opening comprises:
forming a plurality of metal catalyst patterns on a rear surface of the mask substrate;
performing a metal assisted chemical etching process on the mask substrate using the metal catalyst patterns to form preliminary cell openings penetrating the mask substrate; and
removing partition walls between the preliminary cell openings to form the cell opening.

9. The method of claim 2, wherein the inner side surface of the mask substrate defining the cell opening is perpendicular to a rear surface of the mask substrate or has an inclination angle of about 85° or greater with respect to the rear surface of the mask substrate.

10. The method of claim 2, further comprising:
forming a rear inorganic film on a rear surface of the mask substrate; and
patterning the rear inorganic film to form a rear opening which partially exposes the rear surface of the mask substrate.

11. The method of claim 10, wherein the cell opening is formed to penetrate a rear portion of the mask substrate exposed by the rear opening.

12. The method of claim 10, wherein the forming the cell opening comprises:
forming a metal catalyst pattern on a rear portion of the mask substrate exposed by the rear opening; and
performing a metal assisted chemical etching process on the mask substrate using the metal catalyst pattern to form the cell opening.

13. The method of claim 10, wherein the forming the cell opening comprises:
forming a metal catalyst pattern on a rear portion of the mask substrate exposed by the rear opening;
performing a metal assisted chemical etching process on the mask substrate using the metal catalyst pattern to form a first opening extending from the rear surface of the mask substrate in the thickness direction of the mask substrate;
removing the metal catalyst pattern; and
forming a second opening connecting the first opening and the pixel openings through the mask substrate.

14. The method of claim 13, wherein an inner side surface portion of the mask substrate defining the first opening is perpendicular to the rear surface of the mask substrate or has an inclination angle of about 85° or greater with respect to the rear surface of the mask substrate, and
the second opening has a width which gradually decreases from the first opening toward the membrane.

15. The method of claim 14, wherein an inner side surface portion of the mask substrate defining the second opening has an inclination angle of about 54.7° with respect to the rear surface of the mask substrate.

16. The method of claim 13, wherein the second opening is formed by a wet etching process using a tetramethylammonium hydroxide (TMAH) solution, a potassium hydroxide (KOH) solution, or an ethylene diamine pyrocatechol (EDP) solution.

17. The method of claim 13, wherein the forming the cell opening further comprises:
forming a liner pattern on inner side surfaces of the first opening; and
removing the liner pattern after forming the second opening.

18. The method of claim 17, wherein the forming the liner pattern comprises:
forming a rear passivation film on the rear inorganic film and inner surfaces of the first opening and the rear opening; and
removing a portion of the rear passivation film on the rear inorganic film and a portion of the rear passivation film on a bottom surface of the first opening.

19. The method of claim 13, wherein the forming the cell opening further comprises:
forming a front passivation film on the membrane and inner surfaces of the pixel openings after forming the first opening; and
removing the front passivation film after forming the second opening.

20. An electronic device comprising a display panel,
wherein the display panel comprises a backplane substrate and a plurality of light emitting layers formed by using a deposition mask on the backplane substrate,
the deposition mask comprises:
a mask substrate provided with a cell opening; and
a membrane disposed on a front surface of the mask substrate and provided with a plurality of pixel openings communicating with the cell opening,
wherein an inner side surface of the mask substrate defining the cell opening has a stripe-shaped surface profile extending in a thickness direction of the mask substrate, and
the plurality of light emitting layers is formed by a deposition process which provides a vapor-phase light emitting material onto the backplane substrate through the cell opening and the plurality of pixel openings.
